(19) United States
(12) Patent Application Publication
(10) Pub. No.: US 2025/0211202 A1
(43) Pub. Date: Jun. 26, 2025

(54) COMPOSITE FILTER AND COMMUNICATION DEVICE

(71) Applicant: KYOCERA Corporation, Kyoto-shi, Kyoto (JP)

(72) Inventors: Tsuyoshi NAKAI, Soraku-gun (JP); Junichiro TAKIKAWA, Kyotanabe-shi (JP); Hironori KII, Soraku-gun (JP); Tetsuya KISHINO, Nara-shi (JP)

(73) Assignee: KYOCERA Corporation, Kyoto-shi, Kyoto (JP)

(21) Appl. No.: 18/851,413

(22) PCT Filed: Mar. 24, 2023
(86) PCT No.: PCT/JP2023/011729

§ 371 Date: Sep. 26, 2024

(30) Foreign Application Priority Data
Mar. 30, 2022 (JP) 2022-055067

(51) Int. Cl. H03H 9/54

(52) U.S. Cl. CPC H03H 9/54

(57) ABSTRACT

A first filter and a second filter are connected to a first hybrid and a second hybrid such that, when a signal is inputted to one of a common terminal and a first terminal, signals whose phases are shifted by 90° from each other are distributed to the first filter and the second filter, and the distributed signals are made to be in-phase signals and outputted. A difference between the length of wiring line from the first hybrid to the first filter and the length of wiring line from the first hybrid to the second filter is less than half of a maximum dimension of the first filter. A difference between the length of wiring line from the second hybrid to the first filter and the length of wiring line from the second hybrid to the second filter is less than half of the maximum dimension of the first filter.

### DESCRIPTION

### Technical Field

The present disclosure relates to a composite filter including two or more filters, and a communication device including the composite filter.

### Background of Invention

A composite filter including two or more filters is known. Patent Literature 1 discloses a duplexer as a composite filter. The duplexer includes a transmission filter and a reception filter, in which the transmission filter filters a high-frequency signal (transmission signal) inputted from a transmission terminal and outputs the result to an antenna, and the reception filter filters a high-frequency signal (reception signal) inputted from the antenna and outputs the result to a reception terminal. In Patent Literature 1, a 90° hybrid coupler (it may be referred to simply as a “90° hybrid”) is arranged in the front stage and/or rear stage of the transmission filter and the reception filter to reduce nonlinear distortion. Note that the contents of Patent Literature 1 may be incorporated herein by reference.

### CITATION LIST

### Patent Literature

Patent Literature 1: International Publication No. 2022/054896

### SUMMARY

In an aspect of the present disclosure, a composite filter includes a first hybrid, a second hybrid, a first filter system, and a second filter system. The first hybrid is composed of a 90° hybrid coupler and connected to a common terminal. The second hybrid is composed of a 90° hybrid coupler and connected to a first terminal. The first filter system is connected to the common terminal via the first hybrid and connected to the first terminal via the second hybrid to pass a signal of a first pass band. The second filter system is connected to the common terminal via the first hybrid and connected to a second terminal to pass a signal of a second pass band different from the first pass band. The first filter system includes a first filter and a second filter, each of which passes a signal of the first pass band. The first filter and the second filter are connected to the first hybrid and the second hybrid in a connection relationship in which, when a signal is inputted to one of the common terminal and the first terminal, signals whose phases are shifted by 90° from each other are distributed to the first filter and the second filter, and the distributed signals are made to be in-phase signals and outputted to the other of the common terminal and the first terminal. A difference between the length of wiring line from the first hybrid to the first filter and the length of wiring line from the first hybrid to the second filter is less than half of a maximum dimension of the first filter. A difference between the length of wiring line from the second hybrid to the first filter and the length of wiring line from the second hybrid to the second filter is less than half of the maximum dimension of the first filter.

In an aspect of the present disclosure, a communication device includes the above-described composite filter, an antenna connected to the common terminal, and an integrated circuit element connected to the first terminal and the second terminal.

### BRIEF DESCRIPTION OF THE DRAWINGS

FIG. 1 is a circuit diagram illustrating a configuration of a demultiplexer according to a first embodiment.

FIG. 2 is a schematic transparent plan view showing an example of the structure of the demultiplexer of FIG. 1.

FIG. 3 is a schematic transparent side view illustrating the structure of FIG. 2.

FIG. 4 is a perspective view illustrating a portion of a multilayer substrate of the demultiplexer of FIG. 1 in a transparent manner.

FIG. 5 is a cross-sectional view taken along line V-V of FIG. 4.

FIG. 6 is a plan view schematically showing an example of a configuration of a resonator included in the demultiplexer of FIG. 1.

FIG. 7 is a circuit diagram schematically showing an example of a configuration of a demultiplexer body included in the demultiplexer of FIG. 1.

FIG. 8 is a plan view illustrating a configuration of a reception filter system of a demultiplexer according to a second embodiment.

FIG. 9 is a circuit diagram illustrating a configuration of a demultiplexer according to a third embodiment.

FIG. 10 is a circuit diagram illustrating a configuration of a demultiplexer according to a fourth embodiment.

FIG. 11 is a block diagram illustrating a configuration of a communication device as an example of using a demultiplexer according to an embodiment.

### DESCRIPTION OF EMBODIMENTS

Hereinafter, an embodiment according to the present disclosure will be described with reference to the drawings. Note that the drawings to be used in the following description are schematic. Therefore, for example, the dimensional proportions and the like of the drawings do not necessarily match those of the actual product. Further, the dimensional proportions and the like may not match between the drawings. Some specific shapes, dimensions and/or like may be exaggerated, or details may be omitted. However, the foregoing explanation does not deny that the actual shape and/or dimensions may be as illustrated in the drawings or that the features of the shape and/or dimensions may be extracted from the drawings.

In the description of a plurality of aspects, an aspect to be described later is basically be described by focusing only on the differences from the aspect(s) previously described. Matters not specifically described may be assumed to be the same as or similar to the previously described aspect(s) or inferred from the previously described aspect(s). Note that, components corresponding to each other in a plurality of aspects may be denoted by the same reference signs for convenience even if there are differences. Conversely, even components identical to each other may be denoted by different reference signs for convenience of description.

In the present disclosure, when the phase of a signal is described as being “shifted” or the like, the phase may be either advanced or delayed. However, for convenience, when described in the above manner, “shifted” or the like shall mean only one of “advanced” and “delayed” in common with various components, various signals and the like, unless a contradiction or the like arises. For example, when the phase of a second signal is shifted by 90° with respect to the phase of a first signal, and the phase of a fourth signal is shifted by 90° with respect to the phase of a third signal, the shift of the former and the shift of the latter are both advanced by 90° in phase, or both delayed by 90° in phase.

### First Embodiment

### (Outline of Demultiplexer)

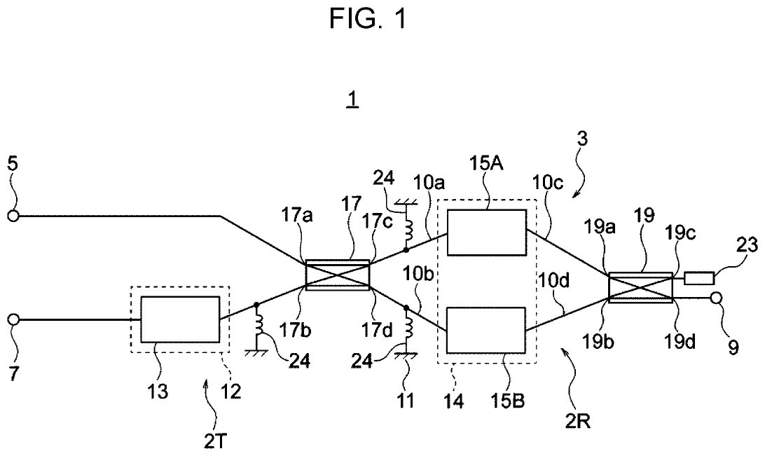

FIG. 1 is a circuit diagram illustrating a configuration of a demultiplexer 1 as a composite filter according to a first embodiment.

More specifically, the demultiplexer 1 is configured as a duplexer. The demultiplexer 1 includes, for example, a transmission path 2T for filtering a transmission signal from a transmission terminal 7 and outputting the result to an antenna terminal 5, and a reception path 2R for filtering a reception signal from the antenna terminal 5 and outputting the result to a reception terminal 9.

The transmission path 2T includes a transmission filter system 12 that directly performs filtering of the transmission signal. The transmission filter system 12 includes a transmission filter 13. The reception path 2R includes a reception filter system 14 that directly performs filtering of the reception signal. The reception filter system 14 includes reception filters 15A and 15B (both of which may be referred to hereinafter simply as a reception filter 15 without distinguishing between the both).

The transmission filter system 12 (transmission filter 13) corresponds to a transmission band. The reception filter system 14 (reception filter 15) corresponds to a reception band. In other words, the pass bands of the transmission filter 13 and the reception filter 15 are different from each other (do not overlap each other). In the demultiplexer 1, the portion that includes the transmission filter 13 and the reception filter 15 and directly contributes to filtering may be referred to as a demultiplexer body 3.

Nonlinear distortion (distortion signal) such as inter-modulation distortion (IMD) is known to occur in the transmission filter 13 and/or the reception filter 15 due to their nonlinearities. In the present disclosure, the inter-modulation distortion has a broad meaning, including passive inter-modulation (PIM), unless otherwise specifically noted. Such nonlinear distortion degrades the characteristics of the demultiplexer 1.

Thus, the demultiplexer 1 includes a first hybrid 17 and a second hybrid 19, each composed of a 90° hybrid coupler. The first hybrid 17 is interposed between the antenna terminal 5, the transmission filter 13, and the reception filters 15A and 15B. The second hybrid 19 is interposed between the reception terminal 9 and the reception filters 15A and 15B. A signal path passing through the reception filter 15A and a signal path passing through the reception filter 15B are formed between the first hybrid 17 and the second hybrid 19.

The first hybrid 17 and the second hybrid 19 perform distribution, phase adjustment, and/or combination on the transmission signal and/or the reception signal. In such a process, for example, the nonlinear distortion is distributed, and the distributed nonlinear distortions are phase reversed from each other and then combined to cancel each other out. That is, the nonlinear distortion is reduced. On the other hand, the demultiplexer 1 basically maintains the strengths of the transmission signal and the reception signal.

An example of the above operations is described below. The nonlinear distortion occurring in the transmission filter 13 and directed to the reception terminal 9 is divided, by the first hybrid 17, into signals whose phases are shifted by 90° from each other and distributed to the reception filters 15A and 15B. When the frequency of the nonlinear distortion is within the reception band, the distributed nonlinear distortion passes through the reception filters 15A and 15B and is inputted to the second hybrid 19. The phases of such nonlinear distortions, whose phases have been shifted by 90° from each other, are further shifted by 90° from each other by the second hybrid 19 to form signals of reverse phase (i.e., signals with a phase shift of 180°). Since such nonlinear distortions of reverse phase cancel each other out, the nonlinear distortion outputted to the reception terminal 9 is reduced.

Here, in the demultiplexer 1 of the present embodiment, the difference between the length of a wiring line 10a from the first hybrid 17 to the reception filter 15A and the length of a wiring line 10b from the first hybrid 17 to the reception filter 15B is made relatively small. For example, the length of the wiring line 10a is equal to the length of the wiring line 10b. The difference between the length of a wiring line 10c from the second hybrid 19 to the reception filter 15A and the length of a wiring line 10d from the second hybrid 19 to the reception filter 15B is made relatively small. For example, the length of the wiring line 10c is equal to the length of the wiring line 10d. Therefore, for example, the length of the wiring lines on the reception filter 15A side is equal to the length of the wiring lines on the reception filter 15B side. As a result, for example, the strength of the nonlinear distortion passing through the reception filter 15A and the strength of the nonlinear distortion passing through the reception filter 15B are likely to be equivalent to each other, and/or the accuracy of the reverse phase is likely to be improved. As a result, the effect of reducing the nonlinear distortion by canceling out the nonlinear distortions of the reverse phase is improved.

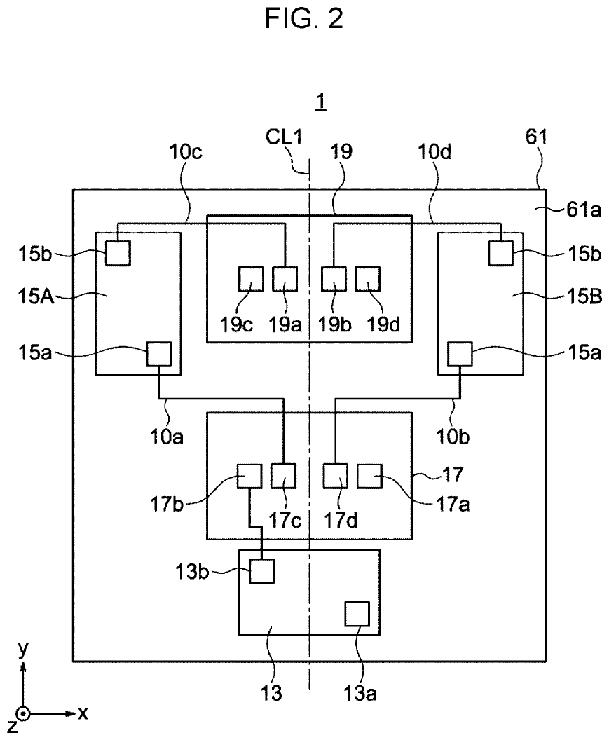

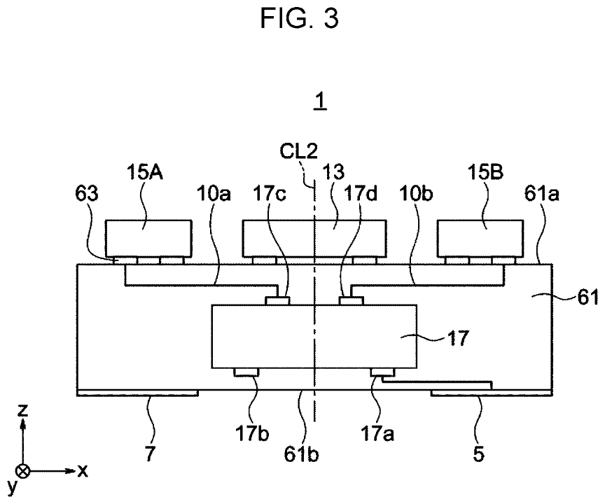

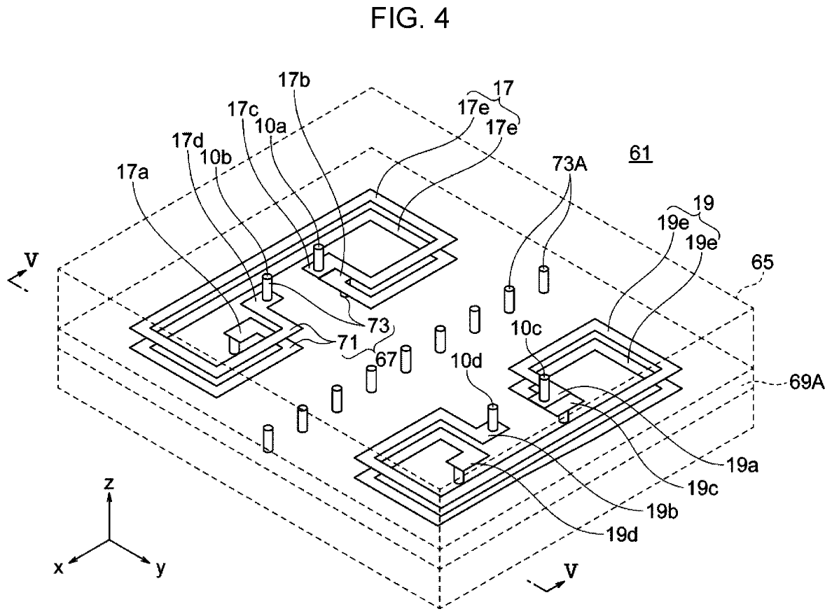

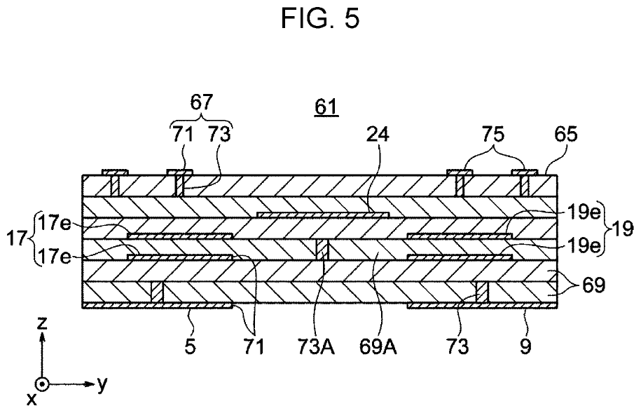

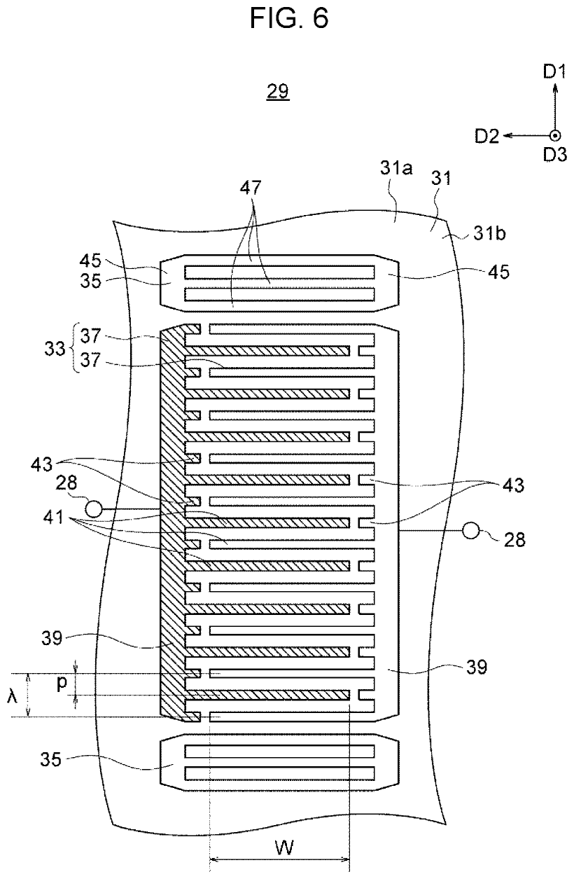

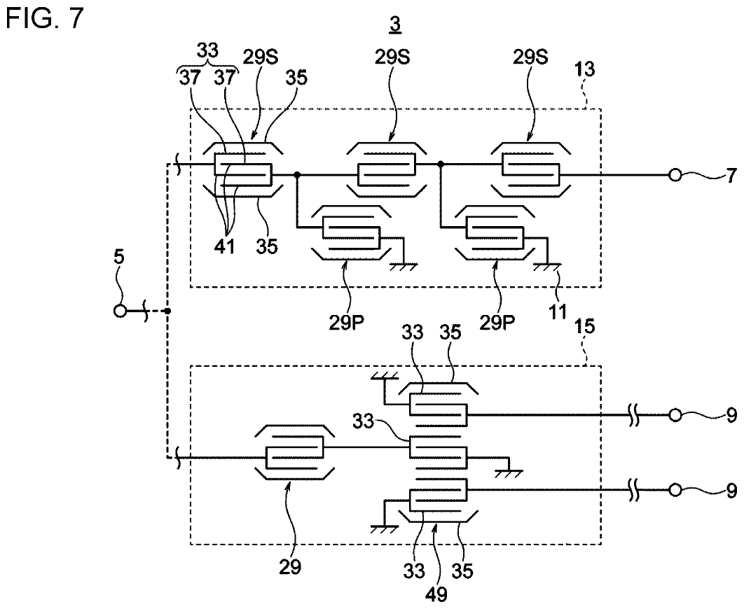

The above is the outline of the first embodiment. Hereinafter, the first embodiment will be described schematically in the following order.
1. Configuration of demultiplexer 1 (FIG. 1)
   1.1. Filter
   1.2. Hybrid
   1.3. Termination resistor
   1.4. Matching element
2. Operation of demultiplexer 1
   2.1. Transmission of transmission signal
   2.2. Transmission of reception signal
   2.3. Example of reducing nonlinear distortion
3. Structure example of demultiplexer 1 (FIGS. 2 and 3)
   3.1. Outline of structure example of demultiplexer 1
   3.2. Position of hybrid
   3.3. Position of filter
   3.4. Position of port of hybrid
   3.5. Position of wiring line
4. Structure example of multilayer substrate (FIGS. 4 and 5)
   4.1. Outline of structure example of multilayer substrate
   4.2. Structure example of hybrid
   4.3. Matching element and others
5. Difference in length between wiring lines
6. Configuration example of filter (FIGS. 6 and 7)
   6.1. Example of acoustic wave element
   6.2. Configuration example of demultiplexer body using acoustic wave filter
7. Summary of first embodiment

In the first section, the basic configuration of the demultiplexer 1 will be described with reference to the circuit diagram of FIG. 1. In the second section, the operation of the demultiplexer 1 will be described. In the first and second sections, the lengths of the wiring lines 10a to 10b will not be mentioned. In the third section, a specific structure example of the demultiplexer 1 will be described. Such a structure example has the effect of, for example, making it easier to make the lengths of the wiring lines 10a to 10d equal. The multilayer substrate described in the section 4 is a component described in the specific structure example of the section 3, and includes the first hybrid 17 and the second hybrid 19. The section 5 describes the allowable ranges of the difference in length between the wiring lines 10a and 10b and the difference in length between the wiring lines 10c and 10d. The section 6 describes an acoustic wave filter as a configuration example of the transmission filter 13 and the reception filter 15.

### (1. Configuration of Demultiplexer)

The outline of the configuration of the demultiplexer 1 has already been described. In addition to the components described above, the demultiplexer 1 may further include, for example, a termination resistor 23 connected to an unused port 19c of the second hybrid 19, and a matching element 24 (or, in another viewpoint, a matching circuit) provided at one or more suitable positions. The components of the demultiplexer 1 are described below.

### (1.1. Filter)

The transmission filter 13 is a bandpass filter having a predetermined transmission band as a pass band. Similarly, the reception filter 15 is a bandpass filter having a predetermined reception band as a pass band. The transmission band and the reception band may, for example, conform to various standards. The transmission band may include two or more transmission bands conforming to a predetermined standard. The same goes for the reception band.

The reception filters 15A and 15B correspond to the same reception band. That is, the pass bands of the reception filters 15A and 15B are identical substantially and/or in design. The reception filters 15A and 15B are configured to be identical or similar to each other and have substantially, or in design, identical characteristics to each other. However, the reception filters 15A and 15B may be finely adjusted to have slightly different pass bands and/or slightly different characteristics.

The specific configuration of the transmission filter 13 and the reception filter 15 may be, for example, a known configuration or an application of a known configuration. For example, the transmission filter 13 and/or the reception filter 15 may be a piezoelectric filter including a piezoelectric body, a dielectric filter using electromagnetic waves in a dielectric body, an LC filter obtained by combining an inductor and a capacitor, or a filter obtained by combining two or more the above-described filters. The piezoelectric filter may be, for example, one that uses an acoustic wave, or one that does not use an acoustic wave (for example, one that uses a piezoelectric vibrator). The acoustic wave is, for example, a surface acoustic wave (SAW), a bulk acoustic wave (BAW), an elastic boundary wave or a plate wave (however, these acoustic waves are not necessarily distinguishable).

### (1.2. Hybrid)

The first hybrid 17 includes four ports 17a to 17d for signal input and/or output, and functions as a distributor, a combiner, and a 90° phase shifter. The configuration of the first hybrid 17 may be, for example, a known configuration or an application of a known configuration. For example, although not particularly illustrated in the drawings, the first hybrid 17 may be of a distributed constant type hybrid or a lumped constant type hybrid. A branch line coupler is well known as the first hybrid 17.

Each of the ports 17a and 17b on the left side of drawing is conducted to each of the ports 17c and 17d on the right side of the drawing. Here, the expression “conducted” means that a signal can flow. Thus, for example, a signal inputted to the port 17a can be outputted from the ports 17c and 17d.

For convenience, the description of the present embodiment may be based on the positional relationship of the ports 17a to 17d in the drawings illustrating the first hybrid 17. However, the positional relationship of the four ports 17a to 17d in the drawings may not necessarily match the positional relationship of the actual four ports 17a to 17d.

The signal inputted to the port 17a on the left side of the drawing is distributed to the ports 17c and 17d on the right side of the drawing. At this time, the distribution ratio (the ratio of the strengths of the two distributed signals) is 1:1. The strengths are, for example, voltage, current and/or power. The phases of the two distributed signals are shifted by 90° from each other.

The phase of the signal before distribution (for example, the signal inputted to the port 17a) may be the same as the phase of one of the two signals after distribution (for example, the signal outputted from the port 17c). In contrast, the phase of the signal before distribution may be different from the phase of both the two signals after distribution. However, for convenience, the description of the present embodiment may be performed as if the phase of the signal before distribution is the same as the phase of one of the two signals after distribution. Specifically, the description of the present embodiment may be performed as if the phases of the signals of the ports having the same position in the up-down direction of the drawing (for example, the ports 17a and 17c) are the same.

Although the case where a signal is inputted to the port 17a has been described as an example, the operations described above are the same or similar when a signal is inputted to each of the other ports 17b to 17d. That is, the signal inputted to one of the two ports located on one side of the left-right direction of the drawing are distributed at a distribution ratio of 1:1 and outputted from the two ports located on the other side of the left-right direction of the drawing. At this time, the phases of the two distributed signals are 90° shifted from each other.

As described above, for convenience, when the phase is shifted, the phase shift refers only to either advanced or delayed in common with various components, various signals and the like. In the expression of the drawings, when a signal is inputted to a port (for example, 17a), the phase of a signal outputted from a port whose position in the up-down direction of the drawing is different from that of the port to which the signal is inputted (for example, 17d) is shifted by 90° from a signal outputted from a port whose position in the up-down direction of the drawing is the same as that of a port to which a signal is inputted (for example, 17c).

Since the component operating as described above is a 90° hybrid, the relationship between the four ports of the first hybrid 17 can be specified from the description of only some of the ports. For example, assume that it has been described that the port 17d is a port from which a signal whose phase is shifted by 90° from the phase of the signal distributed from the port 17a to the port 17c is distributed from the port 17a. Such a description leads to a fact that the port 17a and the remaining port 17b are located on the same side in the left-right direction of drawing, and the port 17c and the port 17d are located on the opposite side, and a fact that the port 17a and the port 17c are located on the same side in the up-down direction of the drawing, and the port 17b and the port 17d are located on the opposite side. When the relationship between the four ports is described with an example in which a signal is distributed from the port 17a as described above, the first hybrid 17 need not be provided in such an aspect that a signal is actually inputted from the port 17a.

When signals are inputted to the ports 17a and 17b, respectively, on the left side of the drawing, the signals are each distributed as described above, and the distributed signals are combined. For example, the signal inputted to the port 17a is designated as a first signal, and the signal inputted to the port 17b is designated as a second signal. The signals obtained by distributing the first signal to the ports 17c and 17d are designated as a third signal and a fourth signal. The phase of the fourth signal is shifted by 90° with respect to the third signal. The signals obtained by distributing the second signal to the ports 17c and 17d are designated as a fifth signal and a sixth signal. The fifth signal is 90° out of phase with respect to the sixth signal. At this time, a signal obtained by combining the third signal and the fifth signal is outputted to the port 17c, and a signal obtained by combining the fourth signal and the sixth signal is outputted to the port 17c. The case where signals are inputted to the two ports 17a and 17b on the left side of the drawing has been described as an example, but the case where signals are inputted to the two ports 17c and 17d on the right side of the drawing is also the same or similar.

As described above, for example, there may be a phase difference between the first signal (inputted to the port 17a) and the third signal (distributed to the port 17c without phase shift), and there may be a phase difference between the second signal (inputted to the port 17b) and the sixth signal (distributed to the port 17d without phase shift). At this time, the two phase differences described above are the same. The two phase differences when the signal is in the opposite direction are also the same as the two phase differences described above.

The first hybrid 17 has been described; the above description of the first hybrid 17 may be applied to the second hybrid 19 by replacing the words “first hybrid 17” with the words “second hybrid 19” and replacing the words “ports 17a to 17d” with the words “ports 19a to 19d”. The specific configurations of the first hybrid 17 (for example, conductor shape and dimensions) and the specific configurations of the second hybrid 19 may be identical to or different from each other.

In the first hybrid 17, the port 17a is connected to the antenna terminal 5. The port 17b is connected to the transmission filter 13. The port 17c is connected to the reception filter 15A. The port 17d is connected to the reception filter 15B.

In the second hybrid 19, the port 19a is connected to the reception filter 15A. The port 19b is connected to the reception filter 15B. The port 19c is, as described above, connected to the termination resistor 23. The port 19d is connected to the reception terminal 9.

### (1.3. Termination Resistor)

The termination resistor 23 has a predetermined resistance value, for example, and connects the port 19c of the second hybrid 19 to a reference potential portion (not illustrated). Thus, for example, reflection of the signal flowing from the ports 19a and/or 19b to the port 19c is reduced. The resistance value of the termination resistor 23 may be appropriately set according to the impedance on the second hybrid 19 side from the termination resistor 23, but is generally 50Ω. The configuration of the termination resistor 23 may be a known configuration or an application of a known configuration. For example, although not particularly illustrated in the drawings, the termination resistor 23 may be an electronic component mounted on a circuit board (for example, a multilayer substrate 61 to be described later), a conductor pattern formed in the multilayer substrate 61, or a conductor pattern formed in a piezoelectric substrate to be described later.

### (1.4. Matching Element)

The matching element 24 is an element constituting a matching circuit. The matching circuit may be regarded as a matching element. The matching element 24 is for improving impedance matching; the matching element 24 may be provided at any position in any configuration, or may not be provided if not necessary.

In FIG. 1, the matching element 24 is provided at the following three positions: between the transmission filter 13 and the first hybrid 17; between the first hybrid 17 and the reception filter 15A; and between the first hybrid 17 and the reception filter 15B. However, these positions are only examples where the matching element 24 is provided, and the matching element 24 may be provided at other positions.

In FIG. 1, an inductor connecting a path through which the signal flows and a reference potential portion 11 is illustrated as the matching element 24, but this is only an example; for example, the matching element 24 may be a capacitor or a resistor, or may be connected in series or parallel to the path through which the signal flows. In FIG. 1, the three matching elements 24 are denoted by the same reference numerals; however, needless to say, they may have different configurations.

### (2. Operation of Demultiplexer)

### (2.1. Transmission of Transmission Signal)

The signal inputted from the outside of the demultiplexer 1 to the transmission terminal 7 (transmission signal) is filtered by the transmission filter 13. As a result, the signal having the frequency of the pass band of the transmission filter 13 is inputted to the port 17b of the first hybrid 17. The signal inputted to the port 17b is distributed to the port 17c and the port 17d. The phase of the signal distributed to the port 17c is shifted by 90° with respect to the phase of the signal distributed to the port 17d.

Since the signal distributed to the port 17c and outputted from the port 17c is a signal having a frequency in the pass band (transmission band) of the transmission filter 13, it is reflected by the reception filter 15A without passing through the reception filter 15A, which has a pass band (reception band) different from the transmission band. Accordingly, the signal outputted from the port 17c returns to the port 17c. Similarly, the signal distributed to the port 17d and outputted from the port 17d is reflected by the reception filter 15B and returns to the port 17d.

The signal returned to the port 17c is distributed to the ports 17a and 17b. At this time, the phase of the signal distributed to port 17b is shifted by 90° with respect to the phase of the signal distributed to the port 17a. Similarly, the signal returned to the port 17d is distributed to the ports 17a and 17b. At this time, the phase of the signal distributed to the port 17a is shifted by 90° with respect to the phase of the signal distributed to the port 17b.

The signal transmitted from the transmission filter 13 to the port 17a via the ports 17b and 17c in this order and the signal transmitted from the transmission filter 13 to the port 17a via the ports 17b and 17d in this order both cause a phase shift of 90° once and are therefore in phase. Accordingly, the two signals are combined and outputted from the port 17a to the antenna terminal 5.

On the other hand, the signal transmitted from the transmission filter 13 to the port 17b via the ports 17b and 17d in this order does not cause a phase shift of 90°. The signal transmitted from the transmission filter 13 to the port 17b via the ports 17b and 17c in this order causes a phase shift of 90° twice. Therefore, the two signals are in reverse phase, cancel each other out, and are not outputted from the port 17b.

For convenience of description, the expression “the signal returned to the port 17c or 17d is distributed to the port 17b” has been used; however, the fact that no signal is outputted from the port 17b means that no signal is substantially distributed to the port 17b. That is, if insertion loss is ignored, the strength of the signal outputted to the antenna terminal 5 is the same as the strength of the signal inputted to the transmission terminal 7.

When focusing only on the first hybrid 17, the port 17b to which the transmission filter 13 is connected is not conducted to the port 17a to which the antenna terminal 5 is connected. As described above, the signal from the transmission filter 13 is transmitted to the antenna terminal 5 by using the reflection of the reception filter 15. Even in such an aspect, the expression “the transmission filter 13 is connected to the antenna terminal 5 via the first hybrid 17” shall be used.

### (2.2. Transmission of Reception Signal)

A signal inputted from the antenna terminal 5 to the port 17a of the first hybrid 17 (reception signal) is distributed to the ports 17c and 17d. The phase of the signal distributed to the port 17d is shifted by 90° with respect to the phase of the signal distributed to the port 17c.

The signal distributed to the port 17c and outputted from the port 17c is inputted to the port 19a of the second hybrid 19 via the reception filter 15A. The signal distributed to the port 17d and outputted from the port 17d is inputted to the port 19b of the second hybrid 19 via the reception filter 15B.

The signal inputted to the port 19a is distributed to the ports 19c and 19d. At this time, the phase of the signal distributed to the port 19d is shifted by 90° with respect to the phase of the signal distributed to the port 19c. Similarly, the signal inputted to the port 19b is distributed to the ports 19c and 19d. At this time, the phase of the signal distributed to the port 19c is shifted by 90° with respect to the phase of the signal distributed to the port 19d.

The signal transmitted from the antenna terminal 5 to the port 19d via the ports 17a and 17c, the reception filter 15A, and the port 19a in this order, and the signal transmitted from the antenna terminal 5 to the port 19d via the ports 17a and 17d, the reception filter 15B, and the port 19b in this order both cause a phase shift of 90° once and are therefore in phase. Accordingly, the two signals are combined and outputted from the port 19d to the reception terminal 9.

On the other hand, the signal transmitted from the antenna terminal 5 to the port 19c via the ports 17a and 17c, the reception filter 15A, and the port 19a in this order does not cause a phase shift of 90°. The signal transmitted from the antenna terminal 5 to the port 19c via the ports 17a and 17d, the reception filter 15B, and the port 19b causes a phase shift of 90° twice. Accordingly, the two signals are in reverse phase, cancel each other out, and are not outputted from the port 19c.

For convenience of description, the expression “the signal inputted to the port 19a or 19b is distributed to the port 19c” has been used; however, the fact that no signal is outputted from the port 19c means that no signal is substantially distributed to the port 19c. That is, if insertion loss is ignored, the strength of the signal outputted to the reception terminal 9 is the same as the strength of the signal inputted to the antenna terminal 5.

### (2.3. Example of Reducing Nonlinear Distortion)

Assume that two signals are inputted to the transmission terminal 7, and nonlinear distortion occurs in the transmission filter 13. The nonlinear distortion has a frequency within the reception band of the reception filter 15, and is passable to pass through the reception filter 15.

The nonlinear distortion inputted from the transmission filter 13 to the port 17b is distributed to the port 17c and the port 17d. The phase of the nonlinear distortion distributed to the port 17c is shifted by 90° with respect to the phase of the nonlinear distortion distributed to the port 17d.

The nonlinear distortion distributed to the port 17c and outputted from the port 17c is inputted to the port 19a of the second hybrid 19 via the reception filter 15A. The nonlinear distortion distributed to the port 17d and outputted from the port 17d is inputted to the port 19b of the second hybrid 19 via the reception filter 15B.

The nonlinear distortion inputted to the port 19a is distributed to the ports 19c and 19d. At this time, the phase of the nonlinear distortion distributed to the port 19d is shifted by 90° with respect to the phase of the nonlinear distortion distributed to the port 19c. Similarly, the nonlinear distortion inputted to the port 19b is distributed to the ports 19c and 19d. At this time, the phase of the nonlinear distortion distributed to the port 19c is shifted by 90° with respect to the phase of the nonlinear distortion distributed to the port 19d.

The nonlinear distortion transmitted from the transmission filter 13 to the port 19d via the ports 17b and 17c, the reception filter 15A, and the port 19a causes a phase shift of 90° twice. The nonlinear distortion transmitted from the transmission filter 13 to the port 19d via the ports 17b and 17d, the reception filter 15B, and the port 19b in this order does not cause a phase shift of 90°. Therefore, the two nonlinear distortions are in reverse phase, cancel each other out, and are not outputted from the port 19d. That is, the nonlinear distortions are not inputted to the reception terminal 9.

On the other hand, the nonlinear distortion transmitted from the transmission filter 13 to the port 19c via the ports 17b and 17c, the reception filter 15A, and the port 19a in this order, and the nonlinear distortion transmitted from the transmission filter 13 to the port 19c via the ports 17b and 17d, the reception filter 15B, and the port 19b in this order both cause a phase shift of 90° once and are therefore in phase. Therefore, the two signals are combined and inputted from the port 19c to the termination resistor 23. By extension, the nonlinear distortion is released to the reference potential portion or the like via the termination resistor 23.

Next, assume that when a transmission signal inputted from the outside to the transmission terminal 7 and passing through the transmission filter 13 and the first hybrid 17 is reflected by the reception filter 15, nonlinear distortion is generated in the reception filter 15. The phase relationship of the nonlinear distortion generated in the reception filter 15A and the reception filter 15B at this time is similar to the phase relationship of the nonlinear distortion generated in the transmission filter 13 and propagated to the reception filters 15A and 15B. Accordingly, due to the same principle as described above, the nonlinear distortion is absorbed by the termination resistor 23 (is not inputted to the reception terminal 9).

### (3. Structure Example of Demultiplexer)

### (3.1. Outline of Structure Example of Demultiplexer)

FIG. 2 is a schematic transparent plan view showing an example of the structure of the demultiplexer 1. FIG. 3 is a schematic transparent side view illustrating the structure of FIG. 2. For convenience, an orthogonal coordinate system xyz is attached to these drawings. Although any direction of the demultiplexer 1 may be used as an upward direction, in the following description, the +z side may be expressed as an upward direction for convenience.

The demultiplexer 1 includes a multilayer substrate 61 and at least one (a plurality of, in the illustrated example) chips (13, 15A and 15B) fixed to the multilayer substrate 61. Although not particularly illustrated in the drawings, the demultiplexer 1 may include an insulating sealing material (for example, a resin) or an insulating cover that covers the illustrated configuration from the +z side. The sealing material or cover may or may not cover the side surface of the multilayer substrate 61.

The multilayer substrate 61 includes, for example, the portion of the demultiplexer 1 other than the filters. For example, the multilayer substrate 61 includes the following components (some components are not illustrated in FIGS. 2 and 3):

the antenna terminal 5, the transmission terminal 7, the reception terminal 9, the first hybrid 17, the second hybrid 19, the termination resistor 23, the matching element 24, and various wiring lines (including the wiring lines 10a to 10d). Some of these components (for example, the termination resistor 23) may be provided in the chips (13, 15A and 15B).

As described above, the first hybrid 17 and the second hybrid 19 are incorporated in the multilayer substrate 61. In other words, these components are not configured as electronic components to be mounted on the multilayer substrate 61, but are configured such that the conductors of the multilayer substrate 61 have appropriate shapes and dimensions. Examples thereof will be described later.

At least one chip constitutes the transmission filter 13 and the reception filters 15A and 15B. In the present embodiment, each of the transmission filter 13 and the reception filters 15A and 15B is configured as one chip. For this reason, in the drawings according to the present embodiment, the filter and the chip are not denoted by separate reference signs. In the following description, the filter and the chip may not be distinguished.

The shape of the multilayer substrate 61 is substantially a thin rectangular parallelepiped. In another viewpoint, the multilayer substrate 61 has, as its front and rear surfaces (the widest surfaces), a first surface 61a (a surface on the +z side) and a second surface 61b (a surface on the −z side). In the multilayer substrate 61, lengths in the x direction, y direction and z direction are arbitrary. As an example, the multilayer substrate 61 has a size that fits into a square with a length of 7 mm or 5 mm per side in plan view. In such a case, the multilayer substrate 61 need not be square. The multilayer substrate 61 may have a longitudinal direction in either the x direction or the y direction, or may have a shape in which the longitudinal direction and the transverse direction are indistinguishable (for example, a square shape). In other words, the relationship between the longitudinal direction of the multilayer substrate 61 and the arrangement position of other components of the demultiplexer 1 is arbitrary. FIG. 2 shows an example of the multilayer substrate 61 having a substantially square shape.

The various chips (13, 15A and 15B) are surface-mounted on, for example, the first surface 61a. The surface-mounting is performed, for example, by bonding pads 75 (see FIG. 5, which is to be described later), which are owned by the multilayer substrate 61 and provided on the first surface 61a, and terminals (for example, terminals 13a, 13b, 15a and 15b of FIG. 2) of the chips opposed to the pads 75 by a conductive bonding material 63 (FIG. 3) interposed therebetween. The mounting of the chip may be performed in a configuration other than that described above. For example, pins of the chips and the pads of the multilayer substrate 61 may be bonded by a conductive bonding material.

In an aspect in which one chip and one filter can be regarded as the same, as in the present embodiment, the lengths of the wiring lines 10a to 10b may be regarded as the lengths of the wiring lines connected to the terminals of the chip. That is, when measuring the length of the wiring line, the lengths of the conductors within the chip (including the terminals of the chip) may not be taken into consideration. Further, when measuring the lengths of the wiring lines 10a to 10b, the thickness of at least one of the pads 75 and the bonding material 63, or the variation thereof, may be ignored within a reasonable range. In the following description, the wiring lines 10a to 10b may be described as not including the pad 75 and the bonding material 63.

Various terminals for connecting the demultiplexer 1 to external devices (such as 5, 7, and 9) are located, for example, on the second surface 61b. More specifically, for example, the various terminals are formed in a pad shape. That is, the demultiplexer 1 is configured as a surface-mounted chip. The positions of the various terminals in the second surface 61b are arbitrary, and for example, the various terminals are positioned along the outer edge of the second surface 61b (for example, at four corners).

### (3.2. Position of Hybrid)

The positions of the first hybrid 17 and the second hybrid 19 in plan view are arbitrary. In the illustrated example, the positions of the first hybrid 17 and the second hybrid 19 in plan view are as follows.

In plan view, the first hybrid 17 and the second hybrid 19 are located on a center line CL1 of the multilayer substrate 61 (see FIG. 2). The center line CL1 is parallel to one side of the rectangular multilayer substrate 61, for example. The center line CL1 may be parallel to the longitudinal direction of the multilayer substrate 61, or parallel to the transverse direction of the multilayer substrate 61, or difficult to distinguish in such a manner. In FIG. 3, in order to indicate the position of the center line CL1 of FIG. 2, a center line CL2 having the same position in the x direction as the center line CL1 is illustrated.

For example, the center of each of the first hybrid 17 and the second hybrid 19 (for example, the geometric center thereof; hereinafter, the same or similar expression may be applied to other elements unless otherwise specified) is located on the center line CL1. In other words, a virtual line (straight line) passing through the center of the first hybrid 17 and the center of the second hybrid 19 substantially coincides with the center line CL1 of the multilayer substrate 61. Unlike the illustrated example, the virtual line may also be shifted from the center line CL1. In such a case, the virtual line may or may not be located in the center region when, for example, the multilayer substrate 61 is divided into 3 or 5 equal portions in a direction orthogonal to the virtual line.

In the example shown in FIG. 2, since the virtual line passing through the center of the first hybrid 17 and the center of the second hybrid 19 coincides with the center line CL1, the two lines are not separately drawn and separately designated with reference signs. In the description of the embodiment, for convenience, the reference sign of the center line CL1 may be used when referring to the virtual line.

The first hybrid 17 (overall) is located on one side (+y side) of the direction in which the virtual line CL1 extends (y direction) with respect to the second hybrid 19 (overall). The distance between the first hybrid 17 and the second hybrid 19 is arbitrary. In the case where the positions of the first hybrid 17 and the second hybrid 19 in the thickness direction of the multilayer substrate 61 are different from each other, for example, the first hybrid 17 and the second hybrid 19 may partially overlap each other in plan view.

The positions of the first hybrid 17 and the second hybrid 19 relative to the center, outer edge and the like of the multilayer substrate 61 in the direction (y direction) along the virtual line CL1 are also arbitrary. In the illustrated example, the first hybrid 17 is located on the +y side more than the center of the multilayer substrate 61. The second hybrid 19 is located closer to the center of the multilayer substrate 61 compared to the first hybrid 17. For example, when the multilayer substrate 61 is divided into 4 equal parts in the y direction, the area of the second hybrid 19 located in the two regions on the center side is larger than the area located in the regions on the both sides.

The positions and sizes of the first hybrid 17 and the second hybrid 19 in the thickness direction (z direction) of the multilayer substrate 61 are also arbitrary. For example, each hybrid may be located away from both the first surface 61a and the second surface 61b of the multilayer substrate 61 (as in the illustrated example), or may be located at least on one of the first surface 61a and the second surface 61b (for example, it may include conductors located on at least one of the first surface 61a and the second surface 61b). The thicknesses of the first hybrid 17 and the second hybrid 19 may be ½ or more of the thickness of the multilayer substrate 61, or may be less than ½ of the thickness of the multilayer substrate 61.

Further, for example, the arrangement range of the first hybrid 17 and the arrangement range of the second hybrid 19 in the z direction may at least partially overlap with each other (as in the illustrated example), or may not overlap with each other. In the illustrated example, the arrangement range of the first hybrid 17 and the arrangement range of the second hybrid 19 in the z direction are the same as each other. Therefore, in the transparent side view of FIG. 3, the second hybrid 19 is hidden by the first hybrid 17 and therefore is not illustrated.

The shapes and sizes of the first hybrid 17 and the second hybrid 19 are also arbitrary. In the illustrated example, the details of the shapes and sizes of the first hybrid 17 and the second hybrid 19 are as follows. Each hybrid is substantially rectangular with the x direction as the longitudinal direction. The length (for example, the maximum length) of each hybrid in the x direction is ⅓ or more and ⅔ or less of the length (for example, the maximum length) of the multilayer substrate 61 in the x direction. The length (for example, the maximum length) of each hybrid in the y direction is less than ⅓ of the length (for example, the maximum length) of the multilayer substrate 61 in the y direction.

### (3.3. Position of Filter)

The positions of the transmission filter 13 and the reception filters 15A and 15B in plan view are arbitrary. In the illustrated example, the details of the positions of the transmission filter 13 and the reception filters 15A and 15B are as follows.

In plan view, the reception filters 15A and 15B are located in line symmetry with respect to the virtual line CL1 (which has been described above) passing through the center of the first hybrid 17 and the center of the second hybrid 19. That is, in both filters, the positions parallel to the virtual line CL1 are substantially the same, and have substantially the same distances from the virtual line CL1.

With such an arrangement, the wiring lines 10a and 10b are easily made into a shape that is in line symmetry with respect to the virtual line CL1, or close to such a shape. By extension, the lengths of the wiring lines 10a and 10b are easily made equal. The same goes for the wiring line 10c and the wiring line 10d. It is needless to say that, even if both filters are positioned in line symmetry with respect to the virtual line CL, there may be unavoidable manufacturing errors.

Even if the positions of the reception filters 15A and 15B are not strictly in line symmetry, the above effect can be achieved. Therefore, to put the arrangement illustrated in the drawings in a generic conceptual way, it can be said that the reception filters 15A and 15B are located on both sides of the virtual line CL in the direction orthogonal to the virtual line CL (x direction), and the ranges of the reception filters 15A and 15B in the direction in which the virtual line CL extends (y direction) overlap (at least partially) each other.

When described in the above manner, the difference between the two filters in the distance between the virtual line CL1 and the filter may be of any magnitude. For example, the difference between the two filters in the distance between the virtual line CL1 and the center of each filter may be ½ or less, ⅓ or less, or ⅕ or less of the maximum length of each filter (or the smaller one if the two filters differ in size) in the x direction, and may be outside the above ranges. Further, the difference in position between the two filters in the direction in which the virtual line CL extends (y direction) may also be of any magnitude. For example, the difference in position between the centers of the two filters may be ½ or less, ⅓ or less, or ⅕ or less of the maximum length of each filter (or the smaller one if the two filters differ in size) in the y direction, and may be outside the above ranges.

The reception filters 15A and 15B are disposed relatively close to the end portions on both sides of the multilayer substrate 61 in the direction orthogonal to the virtual line CL1 (i.e., the end portion on the +x side and the end portion on the −x side)

For example, the distance (for example, the shortest distance) between the reception filter 15A and the end portion on the −x side is ½ or less or ⅓ or less of the length (for example, the maximum length) of the reception filter 15A in the x direction. For example, no other electronic components are mounted between the reception filter 15A and the end portion on the −x side. For example, the reception filter 15A is located on the −x side of the second hybrid 19. The reception filter 15A and the end portion on the −x side have been described as an example; however, the same description also applies to the reception filter 15B and the end portion on the +x side.

In the direction in which the virtual line CL1 extends (y direction), the arrangement ranges of the reception filters 15A and 15B overlap with, for example, the arrangement range of the second hybrid 19. More specifically, for example, ⅓ or more, ½ or more, or ⅔ or more of the length of the reception filter 15A in the y direction may overlap with ⅓ or more, ½ or more, or ⅔ or more of the length of the second hybrid 19 in the y direction. Note that the lower limit of the former and the lower limit of the latter may be combined arbitrarily. The reception filter 15A has been described as an example; however, the same description also applies to the reception filter 15B.

As shown by the positions of the terminals 15a and 15b (FIG. 2) of the reception filters 15A and 15B, both filters may have structures in which one side and the other side (+x side and −x side) of a direction crossing the virtual line CL1 are reversed from each other. In other words, the structures of both filters may be the same except for the orientation in the x direction. Thus, for example, the nonlinear distortions caused by the both filters are easily made equal in magnitude and the lengths of the wiring lines 10a and 10b (and 10c and 10d) are easily made equal. In the illustrated example, since the reception filters 15A and 15B are arranged in line symmetry with respect to the virtual line CL1, the structures of the both filters are in line symmetry with respect to the virtual line CL1.

Note that, even if the both filters have a line symmetric structure or the like, structures that have, depending on whether the orientation in the x direction is the same or opposite, a relatively small influence on the effects intended in the embodiment may be rationally considered to be excluded from consideration. For example, when each filter includes a large number of electrode fingers (which are to be described later), a slight difference in the number of electrode fingers may be allowed. Further, for example, when the relationship between the orientation of the piezoelectric body and the x direction is selected from a plurality of relationships that can be regarded as equivalent to each other, the difference in the relationship may be ignored.

The transmission filter 13 is located on the virtual line CL1 in plan view. More specifically, for example, when the transmission filter 13 is divided into 3 equal portions or 5 equal portions in a direction orthogonal to the virtual line CL1 in plan view (x direction), the center region thereof is located on the virtual line CL1. Further, in the illustrated example, the center of the transmission filter 13 is located on the virtual line CL1 in plan view.

The transmission filter 13 is disposed relatively close to the end portion of the multilayer substrate 61 on the opposite side from the second hybrid 19 in the direction in which the virtual line CL1 extends (i.e., on the −y side). For example, the distance (for example, the shortest distance) between the transmission filter 13 and the end portion on the −y side is ½ or less or ⅓ or less of the length (for example, the maximum length) of the transmission filter 13 in the y direction. For example, no other electronic components are mounted between the transmission filter 13 and the end portion on the −y side. For example, the transmission filter 13 is located on the −y side of the second hybrid 19.

The shapes and sizes of the reception filter 15 and the transmission filter 13 are also arbitrary. For example, in the illustrated example (or in an example similar thereto), the details are as follows. Each of the reception filters 15A and 15B has a substantially rectangular shape with the y direction as the longitudinal direction. The length of each of the reception filters 15A and 15B in the x direction is less than ⅓, less than ¼, or less than ⅕ of the length of the multilayer substrate 61 in the x direction. The length of each of the reception filters 15A and 15B in the y direction is ¼ or more or ⅓ or more, and less than ½ of the length of the multilayer substrate 61 in the y direction. The transmission filter 13 is substantially rectangular with the x direction as the longitudinal direction. The length of the transmission filter 13 in the x direction is ¼ or more or ⅓ or more, and less than ½ of the length of the multilayer substrate 61 in the x direction. The length of the transmission filter 13 in the y direction is less than ⅓, ¼ or ⅕ of the length of the multilayer substrate 61 in the y direction.

### (3.4. Position of Port of Hybrid)

The positions of various ports of the first hybrid 17 and the second hybrid 19 are arbitrary. In the illustrated example, the details of the positions of various ports of the first hybrid 17 and the second hybrid 19 are as follows.

In plan view (see FIG. 2), among the ports 17a to 17d of the first hybrid 17, the ports 17c and 17d connected to the reception filters 15A and 15B are arranged in line symmetry with respect to the virtual line CL1. More specifically, the ports 17a to 17d are arranged in one column in a direction orthogonal to the virtual line CL1 (x direction) and in line symmetry with respect to the virtual line CL1, of which two ports on the center side are the port 17c and the port 17d.

The arrangement of the ports 19a to 19d of the second hybrid 19 in plan view (FIG. 2) is also similar to that described above. That is, the ports 19a and 19b connected to the reception filters 15A and 15B are arranged in line symmetry with respect to the virtual line CL1. More specifically, the ports 19a to 19d are arranged in one column in a direction orthogonal to the virtual line CL1 (x direction) and in line symmetry with respect to the virtual line CL1, of which two ports on the center side are the port 19a and the port 19b.

As illustrated in FIG. 3, among the ports 17a to 17d of the first hybrid 17, the ports 17c and 17d connected to the reception filters 15A and 15B are located on the upper surface (the surface on the +z side) of the first hybrid 17. The remaining ports 17a and 17b are located on the lower surface (the surface on the −z side) of the first hybrid 17. In another viewpoint, the ports 17c and 17d are located closer to the side of the first surface 61a than the ports 17a and 17b. In another viewpoint, the side of the first surface 61a is the side where the reception filters 15A and 15B are located.

Although not illustrated in FIG. 3, the arrangement of the ports 19a to 19d of the second hybrid 19 in the up-down direction is also the same or similar as described above (see FIG. 4, which is to be described later). That is, the ports 19a and 19b connected to the reception filters 15A and 15B are located on the upper surface of the second hybrid 19. The remaining ports 19c and 19d are located on the lower surface of the second hybrid 19. In another viewpoint, the ports 19a and 19b are located closer to the side of the first surface 61a than the ports 19c and 19d.

### (3.5. Position of Wiring Line)

The specific locations and shapes of the wiring lines 10a to 10d and other wiring lines are arbitrary. In the illustrated example, the details of the specific locations and shapes of the wiring lines 10a to 10d and other wiring lines are as follows.

As mentioned in the description of the positions of the reception filters 15A and 15B, the wiring lines 10a and 10b are provided in positions and shapes that are in line symmetry with respect to the virtual line CL1 in plan view (transparent plan view). Further, the wiring lines 10a and 10b are provided in positions and shapes that are in plane symmetry with respect to a symmetric plane including the virtual lines CL1 and CL2. It is needless to say that the line symmetry may have unavoidable manufacturing errors. Rationally, there may be some deviation in the positions and shapes of the line symmetry within a range where the effect described in the embodiment is relatively small. It is needless to say that the wiring lines 10a and 10b are not necessarily provided in the positions and shapes of the line symmetry. The wiring lines 10a and 10b have been described as an example; however, the same description also applies to the wiring lines 10c and 10d.

As described above, the ports 17c and 17d connected to the wiring lines 10a and 10b are located on the upper surface of the first hybrid 17, in other words, on the side of the first surface 61a. Thus, the wiring lines 10a and 10b can extend from the ports 17c and 17d to the reception filters 15A and 15B without extending to the −z side. For example, the wiring lines 10a and/or 10b may have one or more portions extending to the +z side and one or more portions extending parallel to the xy plane. If, unlike the illustrated example, the ports and the filters overlap vertically, the wiring lines 10a and/or 10b may only extend to the +z side. If the ports are located on the first surface 61a, the wiring lines 10a and/or 10b may only extend to the xy plane. The wiring lines 10a and 10b have been described as an example; however, the same description also applies to the wiring lines 10c and 10d.

The above description may be applied to the wiring lines connecting the ports located on the side of the second surface 61b and the terminals located on the second surface 61b by reversing the +z side and the −z side. For example, in FIG. 3, a wiring line 10e connecting the port 17a and the antenna terminal 5 can extend from the port 17a to the antenna terminal 5 without extending to the +z side. The same goes for a wiring line (not illustrated in FIG. 3) connecting the port 19d and the reception terminal 9.

### (4. Structure Example of Multilayer Substrate)

### (4.1. Outline of Structure Example of Multilayer Substrate)

FIG. 4 is a perspective view illustrating a portion of the multilayer substrate 61 in a transparent manner. FIG. 5 is a cross-sectional view taken along line V-V of FIG. 4. These drawings are mainly intended to illustrate a configuration example of a part of the conductor of the multilayer substrate 61, and are probably schematic.

The basic structure and material of the multilayer substrate 61 (circuit board) (i.e., the configuration excluding specific conductor patterns and dimensions for constituting the demultiplexer 1) may be similar to the structure and material of various known printed circuit boards. For example, the multilayer substrate 61 may be an LTCC (low temperature co-fired ceramics) substrate, an HTCC (high temperature co-Fired ceramic) substrate, an IPD (integrated passive device) substrate, or an organic substrate.

Examples of the LTCC substrate include one that is obtained by adding a glass-based material into alumina and that can be fired at a low temperature (for example, around 900° C.). In the LTCC substrate, for example, Cu or Ag may be used as the conductive material. Examples of the IPD substrate include one that is obtained by forming a passive element on a Si substrate. Examples of the organic substrate include one that is obtained by laminating a prepreg impregnated with a resin onto a base material made of glass or the like.

The multilayer substrate 61 includes a substantially insulating plate-like base body 65 and a conductor 67 located within and/or on the surface of the base body 65. The base body 65 may, for example, include a plurality of insulating layers 69 laminated to each other. In FIG. 4, only an insulating layer 69A of the plurality of insulating layers 69 is indicated by a dotted line. The conductor 67 may have, for example, conductor layers 71 located on the upper surface or lower surface (main surface) of the insulating layer 69 and via conductors 73 passing through the insulating layer 69.

In general, the expression “conductor layer” may refer to either the whole or a part of the conductor layer overlapping the upper surface (or the lower surface) of one insulating layer 69. In the description of the embodiment, for convenience, the expression “conductor layer 71” refers to the whole of the conductor layer overlapping the upper surface (or the lower surface) of one insulating layer 69. Thus, it may be said, for example, that two coils and/or the like, which are separated from each other, are composed of the same conductor layer 71.

As can also be understood from the above description of the LTCC substrate and the like, the materials, shapes, and dimensions of the insulating layer 69, the conductor layer 71, and the via conductor 73 are arbitrary. The thickness of the plurality of insulating layers 69 may be the same as each other or may differ from each other at least in part.

### (4.2. Structure Example of Hybrid)

The conductor 67 (and the base body 65) may constitute the first hybrid 17 and the second hybrid 19, as described above, and may constitute wiring lines connected to the first hybrid 17 and the second hybrid 19. The specific structure thereof is arbitrary; however, in the illustrated example, the details will be described as follows.

The first hybrid 17 includes two coils 17e composed of two conductor layers 71 overlapping the upper surface and lower surface of the insulating layer 69A (the insulating layer 69A may be composed of two or more insulating layers). The two coils 17e are substantially provided with the same positions, shapes and dimensions as each other in plan view. The both ends of the two coils 17e (4 end portions in total) are the ports 17a to 17d.

The ports 17c and 17d connected to the reception filters 15A and 15B are located at both ends of the coil 17e on the upper side (+z side). Thus, as described with reference to FIG. 3, the ports 17c and 17d are located on the upper surface of the first hybrid 17. The remaining ports 17a and 17b are located on both ends of the coil 17e on the lower side (−z side). Thus, as described with reference to FIG. 3, the ports 17a and 17b are located on the lower surface of the first hybrid 17.

The portions of the wiring lines 10a and 10b connected to the ports 17c and 17d may be composed of the via conductors 73 extending upward (+z side) from the ports 17c and 17d (as in the illustrated example), or may be composed of the same conductor layer 71 as the conductor layer 71 constituting the ports 17c and 17d. In the illustrated example, the connecting portions may be composed of the via conductors 73 extending downward (−z side) from the ports 17c and 17d. The description in this paragraph may be applied to the connecting portions of the wiring lines connected to the ports 17a and 17b with respect to the ports 17a and 17b, by replacing upward and downward.

The above description of the first hybrid 17 and the wiring lines 10a and 10b may be applied to the second hybrid 19 and the wiring lines 10c and 10d. However, for clarity, the details will be described as follows.

The second hybrid 19 includes two coils 19e composed of two conductor layers 71 overlapping the upper surface and lower surface of the insulating layer 69A. The two coils 19e are substantially provided with the same positions, shapes and dimensions as each other in plan view. The ends of the two coils 19e (4 end portions in total) are the ports 19a to 19d.

The ports 19a and 19b connected to the reception filters 15A and 15B are located at both ends of the coil 19e on the upper side (+z side). Thus, as described with reference to FIG. 3, the ports 19a and 19b are located on the upper surface of the second hybrid 19. The remaining ports 19c and 19d are located on both ends of the coil 19e on the lower side (−z side). Thus, as described with reference to FIG. 3, the ports 19c and 19d are located on the lower surface of the second hybrid 19.

The portions of the wiring lines 10c and 10d connected to the ports 19a and 19b may be composed of the via conductors 73 extending upward (+z side) from the ports 19a and 19b (as in the illustrated example) or may be composed of the same conductor layer 71 as the conductor layer 71 constituting the ports 19a and 19b. In the illustrated example, the connecting portions may be composed of the via conductors 73 extending downward (−z side) from the ports 19a and 19b. The description in this paragraph may be applied to the connecting portions of the wiring lines connected to the ports 19c and 19d with respect to the ports 19a and 19b, by replacing upward and downward.

The first hybrid 17 and the second hybrid 19 are composed of the same conductor layers 71 (and the insulating layer 69A) as each other. That is, the first hybrid 17 and the second hybrid 19 are located on the same layer of the multilayer substrate 61. Thus, as described with reference to FIG. 3, the first hybrid 17 and the second hybrid 19 have the same arrangement ranges in the thickness direction of the multilayer substrate 61. Noted that, as evidenced by the fact that each hybrid includes two layers opposite each other with the insulating layer 69A interposed therebetween, the same “layer” here is not limited to one conductor layer 71 or one insulating layer 69, but includes two or more conductor layers (and the insulating layer(s) 69 interposed therebetween).

### (4.3. Matching Element and Others)

As illustrated in FIG. 5, the conductor layer 71 that overlaps the lower surface of the base body 65 constitutes, for example, various terminals. The various terminals are, for example, the antenna terminal 5, the transmission terminal 7, the reception terminal 9, and a terminal for a reference potential (not illustrated). The reference potential portion 11 illustrated in FIG. 1 may be the terminal for the reference potential described above. The conductor layer 71 that overlaps the upper surface of the base body 65 constitutes, for example, pads 75 on which electronic components are mounted. The electronic components are, for example, the transmission filter 13 and the reception filters 15A and 15B.

The matching element 24 described with reference to FIG. 1 may be composed of one or more conductor layers 71, composed of one or more via conductors 73, or composed of the both. The matching element 24 may or may not have a portion composed of the conductor layers 71 located on the upper surface of the base body 65.

The position of the matching element 24 is also arbitrary. In the example of FIG. 5, the matching element 24 is composed of a layer different from the layer where the first hybrid 17 and the second hybrid 19 are located. That is, the matching element 24 is not composed of the conductor layer 71 constituting the hybrids (17 and 19) and does not have the via conductor 73 passing through the insulating layer 69A included in the hybrids (17 and 19). More specifically, in the illustrated example, the matching element 24 is located closer to the upper surface side (+z side) than the hybrids (17 and 19).

Noted that, similar to the “layer” explained when describing the first hybrid 17 and the second hybrid 19 are located on the same “layer”, the “layers” different from each other described herein are not limited to one conductor layer 71 or one insulating layer 69, but include two or more conductor layers (and the insulating layer(s) 69 interposed therebetween). When the matching element 24 and the hybrids are located on the different layers, for example, there may be an overlap between the end portion of the via conductor 73 and the conductor layer 71, as in the case where the lower end of the via conductor 73 constituting the matching element 24 is positioned on the upper surface of the insulating layer 69A on which the hybrids are located. It is needless to say that the matching element 24 and the hybrids located on different layers may be separated from each other by one or more insulating layers 69.

The plurality of via conductors 73 may include one or more via conductors 73A located between the first hybrid 17 and the second hybrid 19 and connected to the reference potential portion 11 (see FIG. 1 for reference sign). The position, number and/or the like of the via conductors 73A are arbitrary.

In the illustrated example, in plan view, the plurality of via conductors 73A is arranged in a row so as to cross the virtual line CL1 (see FIG. 2). Note that the plurality of via conductors 73A may be arranged in two or more rows, or in a staggered arrangement. The arrangement may be parallel or inclined to the direction orthogonal to the virtual line CL1 (x direction).

The length of the arrangement of the via conductors 73A may or may not span the entire lengths of the first hybrid 17 and the second hybrid 19 in the x direction (if the two lengths are different, for example, the smaller; the same hereinafter), for example. In the latter case, the length of the arrangement may be ⅔ or greater or ⅔ or less of the length of the first hybrid 17 and the second hybrid 19 in the x direction. The center of the all plurality of via conductors 73A (or a center line along the x direction) may be located exactly in the middle of the first hybrid 17 and the second hybrid 19, or may be close to either hybrid.

The via conductors 73A at least pass through the insulating layer 69A included in the first hybrid 17 and the second hybrid 19. That is, in the thickness direction of the multilayer substrate 61, the arrangement range of the via conductors 73A overlaps at least partially with the arrangement ranges of the first hybrid 17 and the second hybrid 19 (in the illustrated example, overlaps with substantially all of the arrangement ranges of the first hybrid 17 and the second hybrid 19, ignoring the thickness of the conductor layer 71). In other words, at least a portion of the via conductors 73A is located in the same layer as the first hybrid 17 and the second hybrid 19 with respect to the concept of a “layer” (which has been described above) that is not limited to one conductor layer 71 or one insulating layer 69.

### (5. Difference in Length Between Wiring Lines)

As described in the description of the outline of the demultiplexer 1 at the beginning with reference to FIG. 1, the difference between the length of the wiring line 10a and the length of the wiring line 10b is relatively small, and the difference between the length of the wiring line 10c and the length of the wiring line 10d is relatively small. The allowable ranges of such differences may be set appropriately.

For example, unlike the arrangements illustrated above, an aspect is assumed that the first hybrid 17 is positioned on one side in the arrangement direction of the reception filters 15A and 15B with respect to both the reception filters 15A and 15B. In such a case, the length of one of the wiring lines 10a and 10b is longer than the length of the other by substantially the length of one filter in the above-described arrangement direction. In comparison with such an aspect, it is considered that an effect can be obtained by reducing the difference between the length of the wiring line 10a and the length of the wiring line 10b. In such a case, the above-described difference may be, for example, less than ½, less than ⅓, or less than ¼ of the maximum dimension of the reception filter 15A or 15B (or the length of the reception filter 15A or 15B in the arrangement direction of the both filters).

The length of the wiring line may be, for example, the length of the center line of the wiring line. For example, the length of the wiring line composed of the conductor layer 71 may be the length of the center line in plan view. The length of the via conductor 73 may be the length of the center line and may be substituted by the thickness of the insulating layer 69 through which the via conductor 73 passes. In cases where the difference in length between the wiring lines is clearly within a predetermined allowable range, such strictness need not be pursued. In cases where the wiring lines 10a and 10b (or the wiring lines 10c and 10d) are clearly designed and/or formed in line symmetry, since the lengths of the both wiring lines are clearly equal, there will be no problem in defining the length of the wiring lines.

In the description of the embodiment, the length of the wiring line basically refers to the spatial length. However, when a comparison of electrical length (electric length) is more reasonable than a comparison of spatial length for part or all of the length, such as in an aspect in which an impedance circuit is interposed, the comparison of electrical length may be made.

### (6. Configuration Example of Filter)

As described above, the transmission filter 13 and/or the reception filter 15 may be a acoustic wave filter that uses an acoustic wave. An example of the configuration of the acoustic wave filter is described below.

### (6.1. Example of Acoustic Wave Element)

FIG. 6 is a plan view schematically illustrating a configuration of an acoustic wave resonator 29 (which may be referred to simply as “resonator 29” hereinafter) as an example of an acoustic wave element included in the acoustic wave filter. In the following description, the words “resonator 29” may be replaced with the words “acoustic wave element” unless there is a contradiction or the like.

Either direction of the resonator 29 may be upward or downward; however, for convenience, in the following, an orthogonal coordinate system consisting of a D1 axis, a D2 axis and a D3 axis is attached to the drawing, and terms such as “upper surface” or “lower surface” may be used with the +D3 side as upward. The D1 axis is defined to be parallel to the propagation direction of an acoustic wave propagating along the upper surface of a piezoelectric body, which is to be described later, the D2 axis is defined to be parallel to the upper surface of the piezoelectric body and orthogonal to the D1 axis, and the D3 axis is defined to be orthogonal to the upper surface of the piezoelectric body. The relationship between the orthogonal coordinate system D1D2D3 and the orthogonal coordinate system xyz illustrated in FIGS. 1 to 5 is arbitrary.

The resonator 29 is composed of a so-called one-port acoustic wave resonator. For example, the resonator 29 outputs a signal inputted from one of two terminals 28 illustrated schematically on both sides of the drawing from the other of the two terminals 28. At this time, the resonator 29 converts an electrical signal to an acoustic wave, and converts an acoustic wave to an electrical signal. As can be understood from the description of FIG. 7, which is to be described later, the terminals 28 may correspond to, for example, the antenna terminal 5, the transmission terminal 7, the reception terminal 9 and the reference potential portion 11.

The resonator 29 includes, for example, a piezoelectric substrate 31 (at least a portion thereof on an upper surface 31a side), an excitation electrode 33 located on the upper surface 31a, and a pair of reflectors 35 located on both sides of the excitation electrode 33. A plurality of resonators 29 may be formed on one piezoelectric substrate 31. That is, the piezoelectric substrate 31 may be shared by a plurality of resonators 29. In the following description, in order to distinguish between a plurality of resonators 29 that share the same piezoelectric substrate 31, the combination of an excitation electrode 33 and a pair of reflectors 35 (the electrode portion of the resonator 29) may be expressed as if they were the resonator 29 (as if the resonator 29 did not include the piezoelectric substrate 31), for convenience.

The piezoelectric substrate 31 has piezoelectric properties at least in a region, on the upper surface 31a, where the resonator 29 is provided. Examples of such a piezoelectric substrate 31 include one in which the entire substrate is composed of a piezoelectric body. Example of such a piezoelectric substrate 31 further include a so-called laminated substrate. The laminated substrate includes a substrate (piezoelectric substrate) formed of a piezoelectric body having the upper surface 31a, and a support substrate that is laminated to the surface opposite to the upper surface 31a of the piezoelectric substrate via an adhesive or directly without the adhesive. The support substrate may or may not have a cavity below the piezoelectric substrate. Examples of the piezoelectric substrate 31 include one that includes a support substrate, and a film formed of a piezoelectric body (piezoelectric film) or a plurality of films including a piezoelectric film formed on a part or the whole main surface of the support substrate on the +D3 side.

A piezoelectric body 31b, which constitutes at least a region, of the piezoelectric substrate 31, where the resonator 29 is provided, is composed, for example, of a single crystal having piezoelectric properties. Examples of the materials constituting such a single crystal include lithium tantalate (LiTaO₃), lithium niobate (LiNbO₃), and quartz crystal (SiO₂). The cut-angle, planar shape, and various dimensions may be set appropriately.

The excitation electrode 33 and the reflectors 35 are composed of a layered conductor provided on the piezoelectric substrate 31. The excitation electrode 33 and the reflectors 35 are made of, for example, the same material with the same thickness as each other. The layered conductor constituting the excitation electrode 33 and the reflectors 35 is, for example, a metal. The metal is, for example, Al or an alloy mainly composed of Al (i.e., an Al alloy). The Al alloy is, for example, an Al—Cu alloy. The layered conductor may be composed of a plurality of metal layers. The thickness of the layered conductor is appropriately set according to the electrical characteristics required for the resonator 29. As an example, the thickness of the layered conductor is 50 nm or more and 600 nm or less.

The excitation electrode 33 is composed of a so-called interdigital transducer (IDT) electrode and includes a pair of comb-shaped electrodes 37, (one of which is hatched for convenience of better visibility). Each comb-shaped electrode 37 includes, for example, a bus bar 39, a plurality of electrode fingers 41 extending in parallel from the bus bar 39, and a plurality of dummy electrodes 43 projecting from the bus bar 39 between the electrode fingers 41. The pair of comb-shaped electrodes 37 is arranged so that the electrode fingers 41 mesh (intersect) with each other.

For example, the bus bar 39 is formed in a long shape extending linearly in the propagation direction (D1 direction) of the acoustic wave with a substantially constant width. The pair of bus bars 39 are opposed to each other in a direction orthogonal to the propagation direction of the acoustic wave (D2 direction). The bus bar 39 may vary in width, or may be inclined with respect to the propagation direction of the acoustic wave.

For example, each electrode finger 41 is formed in a long shape extending linearly in a direction orthogonal to the propagation direction of the acoustic wave (D2 direction) with a substantially constant width. Note that the width of the electrode finger 41 may vary. In each comb-shaped electrode 37, the plurality of electrode fingers 41 is arranged in the propagation direction of the acoustic wave. Further, the plurality of electrode fingers 41 of one comb-shaped electrode 37 and the plurality of electrode fingers 41 of the other comb-shaped electrode 37 are basically arranged alternately.

The pitch p of the plurality of electrode fingers 41 (for example, the distance between the centers of two electrode fingers 41 adjacent to each other) is basically constant within the excitation electrode 33. The excitation electrode 33 may have a portion that is special with respect to the pitch p. Examples of the special portion include a narrow pitch portion in which the pitch p is narrower than the major portion (for example, 80% or more portion), a wide pitch portion in which the pitch p is wider than the major portion, and a thinned portion in which a small number of the electrode fingers 41 are substantially thinned out.

In the following description, when the expression “pitch p” is used, unless otherwise specified, it refers to the pitch of a portion excluding the special portion (i.e., the pitch of the major portion of the plurality of electrode fingers 41). In the major portion of the plurality of electrode fingers 41 from which the special portion is excluded, when the pitch changes, the average value of the pitch of the major portion of the plurality of electrode fingers 41 may be used as the value of the pitch p.

The number of the electrode fingers 41 may be appropriately set according to the electrical characteristics required for the resonator 29. Since FIG. 6 is a schematic view, the number of the electrode fingers 41 illustrated in the drawing is small. Actually, more electrode fingers 41 may be arranged than the number illustrated in the drawing. The same description applies to strip electrodes 47 of the reflectors 35, which will be described later.

The lengths of the plurality of electrode fingers 41 are, for example, equal to each other. It should be noted that the excitation electrode 33 may be so-called apodized, in which the lengths of the plurality of electrode fingers 41 (in another viewpoint, the intersecting widths W) vary according to the position in the propagation direction. The length and width of the electrode finger 41 may be appropriately set according to required electrical characteristics and/or the like.

For example, the dummy electrodes 43 project in a direction orthogonal to the propagation direction of the acoustic wave with a substantially constant width. The width is equal to, for example, the width of the electrode finger 41. The plurality of dummy electrodes 43 is arranged at the same pitch as the plurality of electrode fingers 41, and the tip of the dummy electrode 43 of one comb-shaped electrode 37 faces the tip of the electrode finger 41 of the other comb-shaped electrode 37 via a gap. Note that the excitation electrode 33 may not include the dummy electrode 43.

The pair of reflectors 35 are positioned on both sides of the excitation electrode 33 in the propagation direction of the acoustic wave. Each reflector 35 may be, for example, electrically floating or may be provided with a reference potential. Each reflector 35 is, for example, formed in a lattice shape. That is, the reflector 35 includes a pair of mutually opposed bus bars 45 and a plurality of strip electrodes 47 extending between the pair of bus bars 45. The pitches of the plurality of strip electrodes 47 and the pitches of the electrode fingers 41 and the strip electrodes 47 adjacent to each other are basically equivalent to the pitches of the plurality of electrode fingers 41.

When a voltage is applied to the pair of comb-shaped electrodes 37, a voltage is applied to the piezoelectric body 31b by the plurality of electrode fingers 41, so that the piezoelectric body 31b vibrates. That is, an acoustic wave is excited. Among acoustic waves of various wavelengths propagating in various directions, the acoustic wave propagating in the arrangement direction of the plurality of electrode fingers 41 with the pitch p of the plurality of electrode fingers 41 as approximately half wavelength (λ/2) tends to have a larger amplitude because the plurality of waves excited by the plurality of electrode fingers 41 overlap in phase.

The acoustic wave propagating through the piezoelectric body 31b is converted into an electrical signal by the plurality of electrode fingers 41. At this time, as when the acoustic wave is excited, the intensity of the electric signal converted by the acoustic wave propagating in the arrangement direction of the plurality of electrode fingers 41 with the pitch p of the plurality of electrode fingers 41 as approximately half wavelength (λ/2) tends to be strong.

Due to the above-described action (and other actions whose description is omitted here), the resonator 29 functions as a resonator whose resonance frequency is the frequency of the acoustic wave whose pitch p is approximately half wavelength (λ/2). The pair of reflectors 35 contributes to confining the acoustic wave.

Although not particularly illustrated in the drawings, the resonator 29 may include a protective film (not illustrated) that covers the upper surface 31a of the piezoelectric substrate 31 from above the excitation electrode 33 and the reflectors 35. Such a protective film is made of, for example, an insulating material such as SiO2, and contributes to reducing the probability of corrosion of the excitation electrode 33 and the like and/or compensating for characteristic changes caused by temperature changes in the resonator 29. Further, the resonator 29 may include an additional film that overlaps the upper surface or lower surface of the excitation electrode 33 and the reflectors 35 and has a shape that basically fits into the excitation electrode 33 and the reflectors 35 in transparent plan view. Such an additional film is formed of, for example, an insulating material or a metallic material having different acoustic characteristics from the material of the excitation electrode 33 and the like, and contributes to improving the reflection coefficient of the acoustic wave.

### (6.2. Configuration Example of Memultiplexer Body Using Acoustic Wave Filter)

FIG. 7 is a circuit diagram schematically illustrating a configuration of the demultiplexer body 3 (a portion that includes the transmission filter 13 and the reception filter 15 and that directly contributes to filtering). In FIG. 7, only the demultiplexer body 3 and terminals of the demultiplexer 1 are illustrated. That is, the first hybrid 17, the second hybrid 19 and the like are not illustrated. Only one of the reception filters 15A and 15B is illustrated.

As can be understood from the reference signs indicated at the upper left of the drawing, the comb-shaped electrode 37 is schematically represented by a two-pronged fork shape in the drawing, and the reflector 35 is represented by a single line with both ends bent. In the following description, the words “demultiplexer body 3” may be replaced with the words “demultiplexer 1” unless there is a contradiction or the like.

As described above, the demultiplexer body 3 includes the antenna terminal 5, the transmission terminal 7, the reception terminal 9, the transmission filter 13, and the reception filter 15. The demultiplexer body 3 further includes the reference potential portion 11. The reference potential portion 11 is a part (conductor) to which the reference potential is applied, and more specifically, the reference potential portion 11 may be, for example, a terminal to which the reference potential is applied, or a configuration other than a terminal (for example, a shield).

The antenna terminal 5 and the filters (13 and 15) are connected via the first hybrid 17. In FIG. 7, for convenience, the first hybrid 17 is omitted, and the connection between the antenna terminal 5 and the filter is indicated by a dotted line. The reception terminal 9 and the reception filter 15 are connected via the second hybrid 19. For convenience, in the following description, the connection relationship may be described as if the hybrids (17 and 19) were not provided.

In FIG. 7, unlike FIG. 1, two reception terminals 9 are indicated. This corresponds to the fact that, in the configuration illustrated in FIG. 7, the reception filter 15 outputs a balanced signal including two signals whose phases are opposite to each other. It is needless to say that the reception filter 15 may output an unbalanced signal composed of one signal whose signal level changes with respect to the reference potential (the reception terminal 9 may be one). The configurations described above may be applied to the case where two receiving terminals 9 are provided, by providing the second hybrid 19 for each reception terminal 9 (i.e., providing two hybrids 19 in total).

The transmission filter 13 is composed of, for example, a ladder filter that is configured by connecting a plurality of resonators 29 (29S and 29P) in a ladder-like manner. That is, the transmission filter 13 includes a plurality (one or more) of serial resonators 29S connected in series between the transmission terminal 7 and the antenna terminal 5, and a plurality (one or more) of parallel resonators 29P (parallel arm) connecting the series line (series arm) and the reference potential portion 11.

The reception filter 15 includes, for example, a resonator 29 and a multi-mode filter 49 (which includes a double-mode filter; and the multi-mode filter 49 may be referred to as MM filter 49 hereinafter). The MM filter 49 includes a plurality of (three, in the illustrated example) excitation electrodes 33 arranged in the propagation direction of the acoustic wave and a pair of reflectors 35 arranged on both sides thereof.

The configuration of the transmission filter 13 and the reception filter 15 is only an example, and may be suitably modified. For example, the reception filter 15 may be composed of a ladder filter similar to the transmission filter 13, or conversely, the transmission filter 13 may include an MM filter 49.

In the above constitution, each of the plurality of resonators 29 (resonators 29S and 29P, and the resonator 29 of the reception filter 15) and the MM filter 49 may be an acoustic wave element. The plurality of acoustic wave elements may be provided on one piezoelectric substrate 31 or provided dispersedly on two or more piezoelectric substrates 31. For example, the plurality of resonators 29 constituting the transmission filter 13 may be provided on the same piezoelectric substrate 31. Similarly, the resonator 29 and the MM filter 49 constituting the reception filters 15A and 15B, respectively, may be provided on the same piezoelectric substrate 31.

As described with reference to FIGS. 2 and 3, in the aspect in which the transmission filter 13, and the reception filters 15A and 15B are each configured as one chip (electronic component), for example, one chip may include one piezoelectric substrate 31. The size of one chip in plan view is, for example, approximately the same as the size of one piezoelectric substrate 31. Although not particularly illustrated in the drawings, the chip may be configured as a bare chip including terminals located on the upper surface 31a (the surface on the +D3 side) of the piezoelectric substrate 31, or as a wafer-level package type chip including a cover covering the upper surface 31a and terminals located on the upper surface (the surface on the +D3 side) of the cover. The chip is arranged so that its surface on the +D3 side faces the first surface 61a of the multilayer substrate 61, and is mounted on the multilayer substrate 61 by bonding the two together with the bonding material 63 (see FIG. 3) interposed between the terminals of the chip and the pad 75 (see FIG. 5).

When assuming an aspect different from the example of FIGS. 2 and 3, the reception filters 15A and 15B may be provided on the same piezoelectric substrate 31 as each other. Further, the transmission filter 13 and the reception filters 15A and 15B may be provided on the same piezoelectric substrate 31. For one filter, the plurality of serial resonators 29S may be provided on the same piezoelectric substrate 31, and the plurality of parallel resonators 29P may be provided on the other same piezoelectric substrate 31. One chip may have two or more piezoelectric substrates 31 mounted on a circuit board.

### (7. Summary of First Embodiment)

As described above, in the present embodiment, a composite filter (demultiplexer 1) includes a first hybrid 17, a second hybrid 19, a first filter system (reception filter system 14), and a second filter system (transmission filter system 12). The first hybrid 17 is composed of a 90° hybrid coupler and is connected to a common terminal (antenna terminal 5). The second hybrid 19 is composed of a 90° hybrid coupler and is connected to a first terminal (reception terminal 9). The reception filter system 14 is connected to the antenna terminal 5 via the first hybrid 17 and to the reception terminal 9 via the second hybrid 19, and passes a signal in a first pass band (reception band). The transmission filter system 12 is connected to the antenna terminal 5 via the first hybrid 17 and to a second terminal (transmission terminal 7), and passes a signal in a second pass band (transmission band) different from the reception band. The reception filter system 14 includes a first filter and a second filter (reception filters 15A and 15B) each passing a signal in the reception band. The reception filters 15A and 15B are connected to the first hybrid 17 and the second hybrid 19 in a connection relationship in which, when a signal is inputted to the antenna terminal 5, signals whose phase are shifted by 90° from each other are distributed to the reception filters 15A and 15B, and the distributed signals are made to be in-phase signals and outputted to the reception terminal 9. The difference between the length of wiring line from the first hybrid 17 to the reception filter 15A (the length of a wiring line 10a) and the length of wiring line from the first hybrid 17 to the reception filter 15B (the length of a wiring line 10b) is within a predetermined allowable range. The difference between the length of wiring line from the second hybrid 19 to the reception filter 15A (the length of a wiring line 10c) and the length of wiring line from the second hybrid 19 to the reception filter 15B (the length of a wiring line 10d) is within a predetermined allowable range. The allowable range is, for example, less than half of the maximum dimension of the reception filter 15A (or 15B).

Accordingly, as described above, the effect of canceling out the nonlinear distortion is improved by the reception filters 15A and 15B.

In the present embodiment, the demultiplexer 1 may include a multilayer substrate 61 and at least one chip (see the components 13, 15A and 15B in FIGS. 2 and 3). The multilayer substrate 61 may include a plurality of insulating layers 69, a plurality of conductor layers 71 overlapping the plurality of insulating layers 69, and a plurality of via conductors 73 passing through the plurality of insulating layers 69. The multilayer substrate 61 may include the first hybrid 17 and the second hybrid 19. The first hybrid 17 and the second hybrid 19 may be composed of a part of the plurality of insulating layers 69, the plurality of conductor layers 71, and the plurality of via conductors 73. The at least one chip described above is fixed to the multilayer substrate 61, and the reception filters 15A and 15B and the transmission filter system 12 may be composed of an acoustic wave filter.

In this case, for example, the acoustic wave filter can be used to obtain the steepness of the change in damping force between the pass band and the band outside the pass band. On the other hand, since nonlinear distortion is likely to occur due to the nonlinearity of the piezoelectric body, the configuration according to the embodiment works effectively. Further, miniaturization is facilitated, for example, by mounting the filters on the multilayer substrate 61 in which the first hybrid 17 and the second hybrid 19 are incorporated. Further, the need for impedance matching can be reduced, for example, by configuring the entire demultiplexer 1 as a single chip.

In the present embodiment, when the multilayer substrate 61 is viewed in plan view, the reception filters 15A and 15B may be located on both sides of a direction orthogonal to a virtual line CL1 passing through the center of the first hybrid 17 and the center of the second hybrid 19 (x direction) with respect to the virtual line CL1. Further, the ranges of the reception filters 15A and 15B may overlap (at least partially) with each other in a direction in which the virtual line CL1 extends.

In such a case, the lengths of the wiring lines 10a and 10b are easily made closer to each other and the lengths of the wiring lines 10c and 10d are easily made closer to each other than, for example, in an aspect in which both the reception filters 15A and 15B are located on the +x side with respect to the virtual line CL1. Further, since the distance between the reception filters 15A and 15B is easily secured, the mutual influence between the reception filters 15A and 15B is easily reduced.

In the present embodiment, the reception filters 15A and 15B may have a structure in which one side and the other side of a direction crossing the virtual line CL1 are reversed from each other.

In such a case, for example, the nonlinear distortion occurring in the reception filters 15A and 15B can be made equivalent. Further, as can be understood from FIG. 2, the terminals having the same role are easily arranged in line symmetry with each other, which, by extension, makes it easy to bring the lengths of the wiring lines 10a and 10b closer to each other and to bring the lengths of the wiring lines 10c and 10d closer to each other. As a result, the effect of canceling out the nonlinear distortion is improved.

In the present embodiment, the wiring line 10a connecting the first hybrid 17 and the reception filter 15A and the wiring line 10b connecting the first hybrid 17 and the reception filter 15B may be in line symmetry with respect to the virtual line CL1. The wiring line 10c connecting the second hybrid 19 and the reception filter 15A and the wiring line 10d connecting the second hybrid 19 and the reception filter 15B may be in line symmetry with respect to the virtual line CL1.

In this case, for example, the lengths of the two lines can easily be made equal. Further, for example, the effects of various electronic elements, such as the reception filters 15A and 15B, on the wiring line in terms of electromagnetic field are likely to be equivalent in the wiring lines 10a and 10b (and the wiring lines 10c and 10d). Accordingly, the effect of canceling out the nonlinear distortion is improved.

In the present embodiment, when the multilayer substrate 61 is viewed in plan view, the transmission filter system may be located on the virtual line CL1.

In such a case, for example, when the reception filters 15A and 15B are located on both sides of the direction orthogonal to the virtual line CL1 (x direction) with respect to the virtual line CL1, the transmission filter 13 is easily separated from the reception filters 15A and 15B. Further, for example, by positioning the transmission filter 13, which is less necessary to be disposed in line symmetry with respect to the virtual line CL1, in the virtual line CL1, an arrangement region for electronic elements (for example, the reception filters 15A and 15B) that are relatively more necessary to be disposed in line symmetry is easily secured.

In the present embodiment, when the multilayer substrate 61 is viewed in plan view, the first hybrid 17 and the reception filters 15A and 15B may be positioned on one side (+y side) of the direction in which the virtual line CL1 extends more than the second hybrid 19. The transmission filter system 12 may be positioned on the other side (−y side) of the direction in which the virtual line CL1 extends more than the second hybrid 19. The reception filter 15A may be positioned on one side (−x side) of the direction orthogonal to the virtual line CL1 more than the first hybrid 17. The reception filter 15B may be positioned on the other side (+x side) of the direction orthogonal to the virtual line CL1 more than the first hybrid 17.

In such a case, for example, since the hybrids (17 and 19) and the filters (13 and 15) do not overlap, electromagnetic field interaction between the hybrids and the filters can be reduced. Further, by positioning the reception filters 15A and 15B on both sides of the direction orthogonal to the virtual line CL1 (x direction) with respect to the virtual line CL1, the lengths of the wiring lines 10a and 10b (and the wiring lines 10c and 10d) can be easily brought closer to each other, as described above.

In the present embodiment, the size of the multilayer substrate 61 in plan view may be such that fits into a square with a length of 7 mm per side.

In such a case, for example, the size of the demultiplexer 1 may be relatively small. In such a relatively small demultiplexer 1, interference between the electronic components is likely to occur. However, isolation can be improved, for example, by appropriately dispersing these elements so that the hybrids (17 and 19) and filters (13 and 15) do not overlap, as described above.

In the present embodiment, at least one chip constituting the filters (13, 15A and 15B) may be located on the side of the first surface 61a of the multilayer substrate 61. In the first hybrid 17, the two ports 17c and 17d connected to the reception filters 15A and 15B may be located closer to the side of the first surface 61a than the remaining two ports 17a and 17b. In the second hybrid 19, the two ports 19a and 19b connected to the reception filters 15A and 15B may be located closer to the side of the first surface 61a than the remaining two ports 19c and 19d.

In such a case, for example, the length of the wiring lines 10a to 10d is easily reduced. As a result, interference between the wiring lines can be reduced. Further, by separating the ports vertically, for example, improvement of the isolation between the wiring lines connected to the ports can be expected. Further, when various terminals (5, 7 and 9) are located on a second surface 61b opposite to the first surface 61a, for example, the length of the wiring lines connecting a part of the terminals to the hybrids (17 and 19) is easily reduced.

The multilayer substrate 61 may include a matching element 24. The matching element 24 may be composed of a part of the plurality of insulating layers 69, the plurality of conductor layers 71, and the plurality of via conductors 73. The matching element 24 may be positioned in a layer different from the layer in which the first hybrid 17 and the second hybrid 19 are located.

In such a case, for example, the multilayer substrate 61 in plan view is easily miniaturized. Further, for example, in the case where the matching element 24 is provided to achieve impedance matching between the filters and the hybrids, the matching element 24 is positioned between the filters and the hybrids from both an electrical viewpoint and a spatial viewpoint, so that the configuration is easily simplified.

The first hybrid 17 and the second hybrid 19 may be positioned in the same layer of the multilayer substrate 61. The plurality of via conductors 73 may include via conductors 73A located between the first hybrid 17 and the second hybrid 19 and connected to the reference potential portion 11.

In such a case, for example, the interference of the first hybrid 17 and the second hybrid 19 can be reduced.

In the first embodiment, the demultiplexer 1 is an example of the composite filter. The reception band is an example of the first pass band, and the transmission band is an example of the second pass band. The reception filter system 14 is an example of the first filter system, and the transmission filter system 12 is an example of the second filter system. The reception filters 15A and 15B are examples of the first filter and the second filter, respectively.

### Second Embodiment

As described in the description of the first embodiment, the reception filters 15A and 15B may be located on the same piezoelectric substrate 31. A second embodiment is an example of such an aspect. The details are described below, for example.

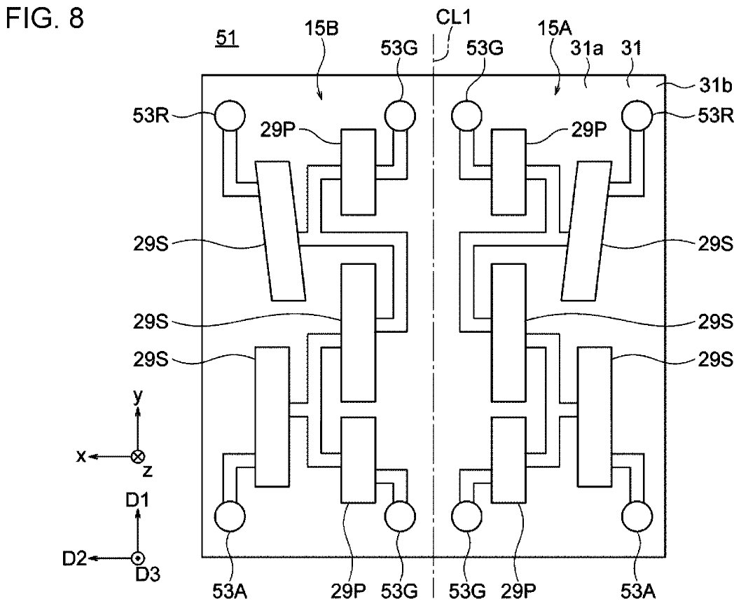

FIG. 8 is a plan view showing an example of a chip 51 including reception filters 15A and 15B. As can be understood from the orthogonal coordinate system D1D2D3, FIG. 8 illustrates an upper surface 31a of a piezoelectric substrate 31. In FIG. 8, resonators 29 (resonators 29S and 29P) are schematically represented by quadrangles.

As can be understood from the orthogonal coordinate system xyz, the chip 51 is mounted on a first surface 61a with the upper surface 31a facing the first surface 61a of a multilayer substrate 61. As can be understood from the virtual line CL1, the chip 51 is located on the virtual line CL1. With respect to the position of the chip 51 in a direction in which the virtual line CL1 extends (y direction), the description of the positions of the reception filters 15A and 15B in the first embodiment may be applied.

The chip 51 includes the reception filters 15A and 15B composed of a ladder filter on the same piezoelectric substrate 31. Specifically, as in FIG. 2 of the first embodiment, for example, the reception filter 15A is located on the −x side and the reception filter 15B is located on the +x side. That is, the reception filters 15A and 15B are located separately from each other on one side and the other side in the x direction, with a predetermined linear boundary line (the virtual line CL1 in the illustrated example) as the boundary.

Each reception filter 15 includes a plurality of terminals (53A, 53R and 53G) electrically connected to the multilayer substrate 61 on which the chip 51 is mounted. The details are described below.

The terminal 53A of each reception filter 15 is a terminal to which a reception signal is inputted, and corresponds to the terminal 15a in FIG. 2. The two terminals 53A are connected to the ports 17c and 17d of the first hybrid 17 and, by extension, connected to the antenna terminal 5 via the first hybrid 17.

The terminal 53R of each reception filter 15 is a terminal from which a reception signal is outputted, and corresponds to the terminal 15b of FIG. 2. The two terminals 53R are connected to the ports 19a and 19b of the second hybrid 19 and, by extension, connected to the reception terminal 9 via the second hybrid 19.

The terminal 53G of each reception filter 15 is a terminal to which the reference potential is applied. The number of the terminals 53G is arbitrary, and there may be terminal(s) 53G shared by the two reception filters 15.

The arrangement of the plurality of terminals 53A, 53R and 53G is arbitrary. In the illustrated example, the two terminals 53A and the two terminals 53R are located at 4 corners of the upper surface 31a of the piezoelectric substrate 31. More specifically, the terminals 53A and 53R of the reception filter 15A are located at 2 corners on one side (−x side) in a direction orthogonal to the virtual line CL1, and the terminals 53A and 53R of the reception filter 15B are located at 2 corners on the other side (+x side) in the direction orthogonal to the virtual line CL1. Further, in the direction in which the virtual line CL1 extends (y direction), the two terminals 53A are located at 2 corners on the same side (−y side), and the two terminals 53R are located at 2 corners on the same side (+y side).

Even in a configuration in which the reception filters 15A and 15B are located on the same piezoelectric substrate 31, the reception filters 15A and 15B may have substantially the same configuration by reversing the +x side and −x side, as in the first embodiment. For example, the reception filters 15A and 15B may have the same number of serial resonators 29S and parallel resonators 29P as each other, and the resonators 29 corresponding to each other may be located and configured in line symmetry with each other. The resonators 29 that are configured to be in line symmetry with each other (identical with each other) may have, for example, the same shape, dimensions, material, orientation with respect to the crystal orientation of the piezoelectric substrate 31, and the like of electrode portions (excitation electrodes 33 and reflectors 35) as each other. However, portions not essential to the filter may be different from each other in the reception filters 15A and 15B.

In the illustrated example, the symmetry axis of the reception filters 15A and 15B coincides with the virtual line CL1. However, the symmetry axis may also not coincide with the virtual line CL1. In the description of the present embodiment, since the symmetry axis coincides with the virtual line CL1, they are not separately drawn and separately designated with reference signs. In the description of the present embodiment, the words “virtual line CL1” may be replaced with the words “symmetry axis” unless there is a contradiction or the like.

As can be understood from the relationship between the virtual line CL1 (or the orthogonal coordinate system xyz) and the orthogonal coordinate system D1D2D3, the propagation direction of the acoustic wave (D1 direction) is along (for example, parallel to) the virtual line CL1. It is needless to say that, unlike the illustrated example, the propagation direction of the acoustic wave and the virtual line CL1 may also intersect each other.

As described above, the propagation direction of the acoustic wave is the direction in which the virtual line CL1 extends (y direction). The reception filters 15A and 15B are located separately on both sides in the x direction. Therefore, the region where the propagation path of the acoustic wave is extended with respect to all resonators 29 of the reception filter 15A does not overlap with the region where the propagation path of the acoustic wave is extended with respect to all resonators 29 of the reception filter 15B.

From the viewpoint of making the region where the propagation path is extended not overlap between the reception filters 15A and 15B, the reception filters 15A and 15B may be separated, only in respect of the excitation electrode 33 (and further, with respect to the intersecting width W), on both sides in a direction orthogonal to the propagation direction of the acoustic wave (x direction) with respect to the predetermined linear boundary line (the virtual line CL1, in the illustrated example). In other words, for example, the reception filters 15A and 15B may not be separated, in respect of the terminals and wiring lines, on both sides in the x direction with respect to the boundary line. In the illustrated example, the reception filters 15A and 15B are ladder filters; however, even in an aspect in which the reception filters 15A and 15B are other filters such as multi-mode filters, the regions extending the propagation path of the acoustic wave may be made not to overlap with each other in the same or similar manner as described above.

In the present embodiment (refer to the first embodiment for a part of the reference signs below), as in the first embodiment, the difference between the length of wiring line from the first hybrid 17 to the reception filter 15A (i.e., the length of the wiring line 10a) and the length of wiring line from the first hybrid 17 to the reception filter 15B (i.e., the length of the wiring line 10b) is within a predetermined allowable range. Further, the difference between the length of wiring line from the second hybrid 19 to the reception filter 15A (i.e., the length of the wiring line 10c) and the length of wiring line from the second hybrid 19 to the reception filter 15B (i.e., the length of the wiring line 10d) is within a predetermined allowable range. Accordingly, the same effect as in the first embodiment is achieved. In the present embodiment, the lengths of the wiring lines 10a to 10c may be lengths from the terminal 53A or 53R to the hybrids.

In the present embodiment, the reception filters 15A and 15B may be located on the same piezoelectric substrate 31. When the multilayer substrate 61 is viewed in plan view, the piezoelectric substrate 31 is located on the virtual line CL1 passing through the center of the first hybrid 17 and the center of the second hybrid 19.

Thus, for example, the reception filters 15A and 15B is easily to be arranged in line symmetry with respect to the virtual line CL1. By extension, the difference in length between the wiring lines 10a and 10b (and the difference in length between the wiring lines 10c and 10d) is easily to be reduced.

In the present embodiment, the reception filters 15A and 15B may each include a plurality of excitation electrodes 33 located on the upper surface 31a of the piezoelectric substrate 31. The propagation direction of the acoustic wave associated with the plurality of excitation electrodes 33 may be along the virtual line CL1. In a plan view of the upper surface of the piezoelectric substrate 31, the plurality of excitation electrodes 33 of the reception filter 15A and the plurality of excitation electrodes 33 of the reception filter 15B may be located separately from each other on one side and the other side in a direction orthogonal to the propagation direction of the acoustic wave.

In such a case, for example, as described above, the regions extending the propagation direction of the acoustic wave do not overlap between the reception filters 15A and 15B. As a result, interference between the reception filters 15A and 15B is reduced.

The two terminals 53A and 53R of the reception filter 15A connected to the first hybrid 17 and the second hybrid 19 may be located at 2 corners, among the 4 corners of the piezoelectric substrate 31, on one side (−x side) in the direction orthogonal to the virtual line CL1. The two terminals 53A and 53R of the reception filter 15B connected to the first hybrid 17 and the second hybrid 19 may be located at 2 corners, among the 4 corners of the piezoelectric substrate 31, on the other side (+x side) in the direction orthogonal to the virtual line CL1.

In such a case, for example, the terminals of the both filters are easily separated from each other. As a result, isolation of the both filters can be improved. Further, since the wiring lines 10a and 10b are symmetrical to each other, the difference in length between them can be reduced easily. The same description applies to the wiring lines 10c and 10d.

### Third Embodiment

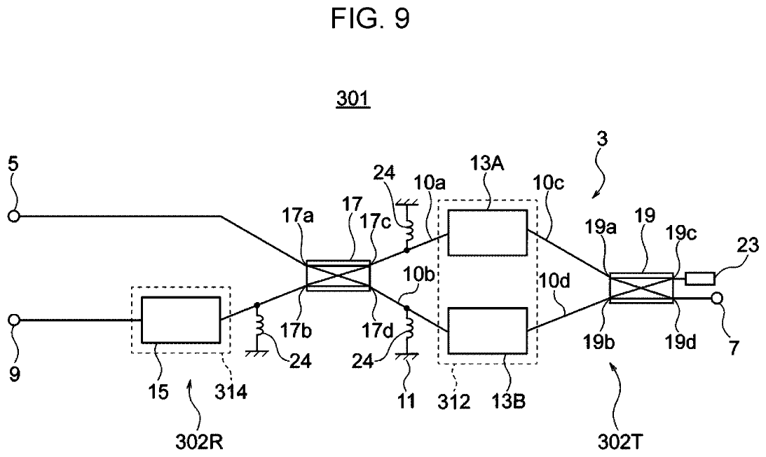

FIG. 9 is a circuit diagram illustrating a configuration of a demultiplexer 301 as a composite filter according to a third embodiment.

In short, the demultiplexer 301 has a configuration obtained by replacing the transmission filter 13 and the reception filter 15 in the demultiplexer 1 of the first embodiment with each other. The details are described below.

A transmission path 302T includes a second hybrid 19, a transmission filter system 312, and a first hybrid 17, in order from a transmission terminal 7 to an antenna terminal 5. Unlike the first embodiment, the transmission filter system 312 includes two transmission filters 13 (13A and 13B). Regarding the connection relationship of these components, the description of the connection relationship in the reception path 2R in the first embodiment may be applied. However, the words “reception filters 15A and 15B (15)” are replaced with the words “transmission filters 13A and 13B (13)”, and the words “reception terminal 9” are replaced with the words “transmission terminal 7”.

Similar to the two reception filters 15 in the first embodiment, the two transmission filters 13 correspond to the same pass band (however, unlike the first embodiment, the same pass band is a transmission band). The configuration and characteristics of the two transmission filters 13 may be the same or similar as those of the two reception filters 15 in the first embodiment.

A reception path 302R includes a reception filter system 314 and the first hybrid 17, in order from the antenna terminal 5 to a reception terminal 9. Unlike the first embodiment, the reception filter system 314 includes one reception filter 15. Regarding the connection relationship of these components, the description of the connection relationship in the transmission path 2T in the first embodiment may be applied. However, the words “transmission filter 13” are replaced with the words “reception filter 15”, and the words “transmission terminal 7” are replaced with the words “reception terminal 9”.

Even in such a demultiplexer 301, the strengths of the transmission signal and the reception signal are maintained. On the other hand, the nonlinear distortion passing through the transmission filter 13A and the nonlinear distortion passing through the transmission filter 13B cancel each other out. As in the first embodiment, the difference in length between wiring lines 10a and 10b and the difference in length between wiring lines 10c and 10d are within a predetermined allowable range, thereby improving the effect of cancelling out the nonlinear distortion. The descriptions of FIGS. 2 to 8 in the first and second embodiments may be applied to the present embodiment by appropriately replacing the words “transmission”, “reception” and the like.

In the third embodiment, the demultiplexer 301 is an example of the composite filter. The transmission band is an example of the first pass band, and the reception band is an example of the second pass band. The transmission filter system 312 is an example of the first filter system, and the reception filter system 314 is an example of the second filter system. The transmission filters 13A and 13B are examples of the first filter and the second filter, respectively.

### Fourth Embodiment

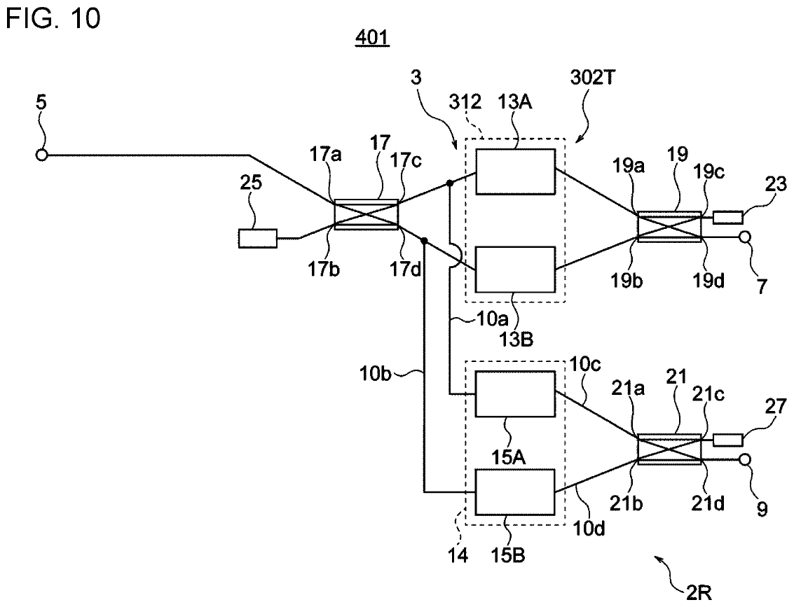

FIG. 10 is a circuit diagram illustrating a configuration of a demultiplexer 401 as a composite filter according to a fourth embodiment.

In short, the demultiplexer 401 is a combination of the first embodiment and the third embodiment. As can be understood from the comparison of FIGS. 1 and 10, in the demultiplexer 401, a reception path 2R may be the same as that in the first embodiment. As can be understood from the comparison of FIGS. 9 and 10, in the demultiplexer 401, a transmission path 302T may be the same as that in the third embodiment.

As described above, the reception path 2R may be the same as that in the first embodiment. However, for convenience, the hybrid and termination resistor included in the reception path 2R are denoted by different reference signs from those in the first embodiment. Specifically, in FIG. 10, a third hybrid 21 and ports 21a to 21d correspond to the second hybrid 19 and the ports 19a to 19d in FIG. 1. In FIG. 10, a termination resistor 27 corresponds to the termination resistor 23 in FIG. 1.

A termination resistor 25 may be connected to a port 17b of a first hybrid 17. The above description of the termination resistor 23 may be applied to the termination resistor 25.

Even in such a demultiplexer 401, the strengths of the transmission signal and the reception signal are maintained. On the other hand, the nonlinear distortion passing through the reception filter 15A and the nonlinear distortion passing through the reception filter 15B cancel each other out. As in the first embodiment, the difference in length between wiring lines 10a and 10b and the difference in length between wiring lines 10c and 10d are within a predetermined allowable range, thereby improving the effect of cancelling out the nonlinear distortion.

Although it has been described above that the difference in length between the wiring lines associated with the reception filters 15A and 15B is within the allowable range, the same description may be applied to the transmission filters 13A and 13B. However, only one of the difference in length between the wiring lines associated with the reception filters 15A and 15B and the difference in length between the wiring lines associated with the transmission filters 13A and 13B may be within an allowable range.

### <Module and Communication Device>

The composite filter may be used, for example, in a communication module and/or communication device. The following is an example. In the following description, the reference sign of the demultiplexer 1 of the first embodiment is used for convenience, but the demultiplexer of other embodiments may be used.

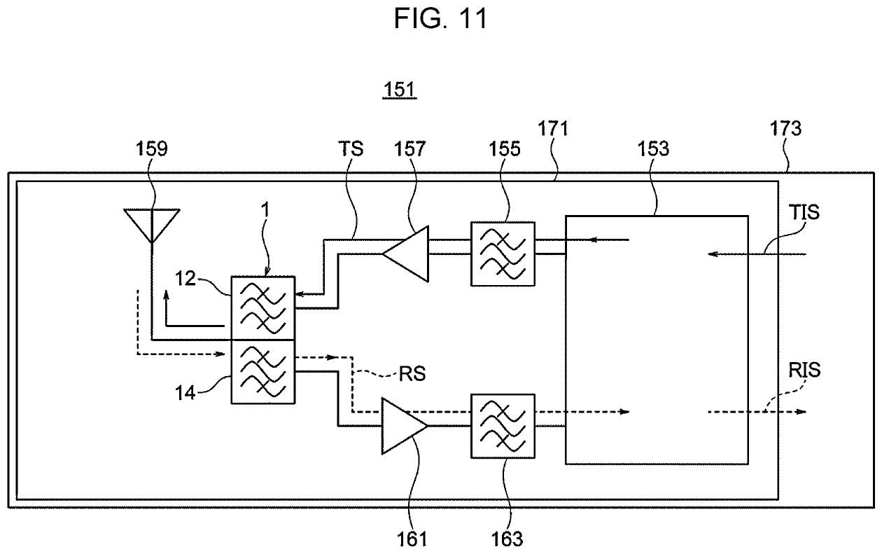

FIG. 11 is a block diagram illustrating a main part of a communication device 151 as an example of using the demultiplexer 1. The communication device 151 includes a module 171 and a housing 173 for housing the module 171

The module 171 performs radio communication using radio waves and includes the demultiplexer 1. Here, in the demultiplexer 1, only a transmission filter system 12 and a reception filter system 14 are illustrated, and hybrids and the like are not illustrated.

In the module 171, a transmission information signal TIS, which contains information to be transmitted, is modulated and frequency-raised by (conversion of a carrier frequency to a high-frequency signal) by an RF-IC (radio frequency integrated circuit) 153 (which is an example of an integrated circuit element) to become a transmission signal TS. The transmission signal TS is amplified by a bandpass filter 155 to remove unwanted components outside the passband for transmission, amplified by an amplifier 157, and inputted to the demultiplexer 1 (transmission terminal 7). The demultiplexer 1 (transmission filter system 12) removes unwanted components other than the passband for transmission from the inputted transmission signal TS, and outputs the transmission signal TS after removing the unwanted components to an antenna 159 from the antenna terminal 5. The antenna 159 converts the inputted electrical signal (transmission signal TS) into a radio signal (radio wave) and transmits the radio signal.

In the module 171, the radio signal (radio wave) received by the antenna 159 is converted into an electrical signal (reception signal RS) by the antenna 159 and inputted to the demultiplexer 1 (antenna terminal 5). The demultiplexer 1 (reception filter system 14) removes unwanted components outside the passband for reception from the inputted reception signal RS and outputs the reception signal RS after removing the unwanted components to an amplifier 161 from the reception terminal 9. The outputted reception signal RS is amplified by the amplifier 161, and unwanted components outside the passband for reception are removed by a bandpass filter 163. The reception signal RS is frequency reduced and demodulated by the RF-IC 153 to form a reception information signal RIS.

The transmission information signal TIS and the reception information signal RIS may be a low-frequency signal (baseband signal) containing appropriate information, for example, an analog audio signal or a digitized audio signal. The passband of the radio signal may be set appropriately. The modulation method may be phase modulation, amplitude modulation, frequency modulation, or any combination of any two or more of these modulations. The circuit method may be a direct conversion method, which has been illustrated, or may be any other suitable methods, such as a double super heterodyne method. FIG. 11 schematically illustrates only the main part, and a low-pass filter, an isolator, and/or the like may be added at appropriate position(s), or the position(s) of the amplifiers and/or the like may be changed.

The module 171 has, for example, the components from the RF-IC 153 to the antenna 159 on the same circuit board. That is, the demultiplexer 1 is modularized by being combined with other components. Note that the ladder filters may be included in the communication device 151, instead of being modularized. Further, the components illustrated as components of the module 171 may be located outside the module or may not be housed in the housing 173. For example, the antenna 159 may be exposed outside the housing 173.

The techniques according to the present disclosure are not limited to the above embodiments, but may be implemented in various aspects.

For example, the composite filter is not limited to a duplexer. For example, the composite filter may include, as the first filter system and the second filter system, two reception paths with different pass bands or two transmission paths with different pass bands. The composite filter may include other filter system(s) in addition to the first filter system and the second filter system. For example, the composite filter may be a triplexer including three filter systems or a quadplexer including four filter systems.

Further, for example, the structure of the demultiplexer is not limited to those illustrated in FIGS. 2 to 5. For example, the hybrids may not be incorporated in a multilayer substrate (circuit board). Further, both a chip constituting the filters and a chip constituting the hybrids may be mounted on the circuit board. In such a case, the circuit board may not be a multilayer substrate. Further, for example, the demultiplexer may not be configured as a surface-mounted chip component, but as a module in which various electronic components are mounted on a relatively large circuit board.

### REFERENCE SIGNS

1 demultiplexer (composite filter)

12 transmission filter system (second filter system)

13 transmission filter

14 reception filter system (first filter system)

15A reception filter (first filter)

15B reception filter (first filter)

17 first hybrid

19 second hybrid

1. A composite filter comprising:
a first hybrid composed of a 90° hybrid coupler and connected to a common terminal;
a second hybrid composed of a 90° hybrid coupler and connected to a first terminal;
a first filter system connected to the common terminal via the first hybrid and connected to the first terminal via the second hybrid to pass a signal of a first pass band; and
a second filter system connected to the common terminal via the first hybrid and connected to a second terminal to pass a signal of a second pass band different from the first pass band,
wherein
the first filter system includes a first filter and a second filter, each of which passes a signal of the first pass band,
the first filter and the second filter are connected to the first hybrid and the second hybrid in a connection relationship in which, when a signal is inputted to one of the common terminal and the first terminal, signals whose phases are shifted by 90° from each other are distributed to the first filter and the second filter, and the distributed signals are made to be in-phase signals and outputted to the other of the common terminal and the first terminal,
a difference between the length of wiring line from the first hybrid to the first filter and the length of wiring line from the first hybrid to the second filter is less than half of a maximum dimension of the first filter, and
a difference between the length of wiring line from the second hybrid to the first filter and the length of wiring line from the second hybrid to the second filter is less than half of the maximum dimension of the first filter.

2. The composite filter according to claim 1, further comprising:
a multilayer substrate that includes a plurality of insulating layers, a plurality of conductor layers overlapping the plurality of insulating layers, and a plurality of via conductors passing through the plurality of insulating layers, and that includes the first hybrid and the second hybrid composed of a part of the plurality of insulating layers, the plurality of conductor layers and the plurality of via conductors; and
at least one chip that is fixed to the multilayer substrate and that constitutes the first filter system and the second filter system by an acoustic wave filter.

3. The composite filter according to claim 2, wherein, when the multilayer substrate is viewed in plan view, the first filter and the second filter are located on either side of a direction orthogonal to a virtual line passing through the center of the first hybrid and the center of the second hybrid, with respect to the virtual line, and the ranges of the first hybrid and the second hybrid in a direction in which the virtual line extends overlap each other.

4. The composite filter according to claim 3, wherein the first filter and the second filter have a structure in which one side and the other side of a direction crossing the virtual line are reversed from each other.

5. The composite filter according to claim 3, wherein
a wiring line connecting the first hybrid and the first filter and a wiring line connecting the first hybrid and the second filter are in line symmetry with respect to the virtual line, and
a wiring line connecting the second hybrid and the first filter and a wiring line connecting the second hybrid and the second filter are in line symmetry with respect to the virtual line.

6. The composite filter according to claim 2, wherein, when the multilayer substrate is viewed in plan view, the second filter system is located on the virtual line.

7. The composite filter according to claim 6, wherein, when the multilayer substrate is viewed in plan view:
the first hybrid, the first filter and the second filter are located on one side of the direction in which the virtual line extends more than the second hybrid,
the second filter system is located on the other side of the direction in which the virtual line extends more than the second hybrid,
the first filter is located on one side of the direction orthogonal to the virtual line more than the first hybrid, and
the second filter is located on the other side of the direction orthogonal to the virtual line more than the first hybrid.

8. The composite filter according to claim 7, wherein the multilayer substrate has a size that fits into a square with a length of 7 mm per side in plan view.

9. The composite filter according to claim 2, wherein
the at least one chip is located on the side of a first surface of the multilayer substrate,
in the first hybrid, two ports connected to the first filter and the second filter are located closer to the side of the first surface than the remaining two ports, and
in the second hybrid, two ports connected to the first filter and the second filter are closer to the side of the first surface than the remaining two ports.

10. The composite filter of claim 2, wherein the multilayer substrate includes a matching element that is composed of a part of the plurality of insulating layers, the plurality of conductor layers and the plurality of via conductors, and that is located in a layer different from the layer where the first hybrid and the second hybrid are located.

11. The composite filter according to claim 2, wherein
the first hybrid and the second hybrid are located in the same layer of the multilayer substrate, and
the plurality of via conductors includes a via conductor located between the first hybrid and the second hybrid and connected to a reference potential portion.

12. The composite filter according to claim 2, wherein
the first filter and the second filter are located on the same piezoelectric substrate included in the at least one chip, and
when the multilayer substrate is viewed in plan view, the piezoelectric substrate is located on a virtual line passing through the center of the first hybrid and the center of the second hybrid.

13. The composite filter according to claim 12, wherein
the first filter and the second filter each includes a plurality of excitation electrodes located on an upper surface of the piezoelectric substrate,
the propagation direction of an acoustic wave associated with the plurality of excitation electrodes is along the virtual line, and
in a plan view of the upper surface of the piezoelectric substrate, the plurality of excitation electrodes of the first filter and the plurality of excitation electrodes of the second filter are located separately on one side and the other side in a direction orthogonal to the propagation direction.

14. The composite filter according to claim 12, wherein
two terminals of the first filter connected to the first hybrid and the second hybrid are located at two corners, among four corners of the upper surface of the piezoelectric substrate, on one side in a direction orthogonal to the virtual line, and
two terminals of the second filter connected to the first hybrid and the second hybrid are located at two corners, among the four corners of the upper surface of the piezoelectric substrate, on the other side in the direction orthogonal to the virtual line.

15. The composite filter according to claim 1, wherein
the first filter system is a reception filter that filters a signal transmitted from the common terminal to the first terminal, and
the second filter system is a transmission filter that filters a signal transmitted from the second terminal to the common terminal.

16. A communication device comprising:
the composite filter according to claim 1;
an antenna connected to the common terminal; and
an integrated circuit element connected to the first terminal and the second terminal.
